(19) United States
(12) Patent Application Publication
(10) Pub. No.: US 2026/0068229 A1
(43) Pub. Date: Mar. 5, 2026

(54) SEMICONDUCTOR DEVICE, DISPLAY DEVICE AND METHOD FOR MANUFACTURING SEMICONDUCTOR DEVICE

(71) Applicant: Japan Display Inc., Tokyo (JP)

(72) Inventors: Akihiro HANADA, Tokyo (JP); Hajime WATAKABE, Tokyo (JP); Takuo KAITOH, Tokyo (JP); Motochika YUKAWA, Tokyo (JP)

(73) Assignee: Japan Display Inc., Tokyo (JP)

(21) Appl. No.: 19/311,043

(22) Filed: Aug. 27, 2025

(30) Foreign Application Priority Data
Sep. 4, 2024 (JP) 2024-151936
Aug. 19, 2025 (JP) 2025-136282

(51) Int. Cl. H10D 30/67; H10K 59/121

(52) U.S. Cl. CPC H10D 30/6755; H10D 30/6736; H10K 59/1213

(57) ABSTRACT

A semiconductor device includes an oxide semiconductor layer, a gate insulating layer on the oxide semiconductor layer, a metal oxide layer having an opening overlapping at least a portion of the oxide semiconductor layer and contacting an upper surface of the gate insulating layer in a region not overlapping the oxide semiconductor layer, and a gate electrode on the gate insulating layer in a region overlapping the oxide semiconductor layer.

### CROSS REFERENCE TO RELATED APPLICATIONS

This application claims the benefit of priority to Japanese Patent Application No. 2024-151936, filed on Sep. 4, 2024 and Japanese Patent Application No. 2025-136282, filed on Aug. 19, 2025, the entire contents of which are incorporated herein by reference.

### FIELD

An embodiment of the present invention relates to a semiconductor device using an oxide semiconductor, a display device including the semiconductor device, and a method for manufacturing the semiconductor device.

### BACKGROUND

In recent years, a semiconductor device using an oxide semiconductor has been developed instead of a silicon semiconductor using amorphous silicon, low-temperature polysilicon, single-crystal silicon, and the like (see, for example, Japanese laid-open patent publication No. 2018-006730). For example, a transistor that utilizes an oxide semiconductor layer containing an oxide semiconductor as a channel can be manufactured in a simple structure and low temperature process, as well as a transistor that contains an amorphous silicon layer. The transistor containing the oxide semiconductor layer is known to have higher field-effect mobility than the transistor containing the amorphous silicon layer.

### SUMMARY

A semiconductor device in one embodiment of the invention includes an oxide semiconductor layer, a gate insulating layer on the oxide semiconductor layer, a metal oxide layer having an opening overlapping at least a portion of the oxide semiconductor layer and contacting an upper surface of the gate insulating layer in a region not overlapping the oxide semiconductor layer, and a gate electrode on the gate insulating layer in a region overlapping the oxide semiconductor layer.

A method for manufacturing a semiconductor device in one embodiment of the invention includes forming an oxide semiconductor layer on an insulating surface, forming a gate insulating layer on the oxide semiconductor layer, forming a metal oxide layer having an opening overlapping at least a portion of the oxide semiconductor layer and in contact with an upper surface of the gate insulating layer, forming a gate electrode on the gate insulating layer, and injecting an impurity to the oxide semiconductor layer via the gate insulating layer.

### BRIEF DESCRIPTION OF THE DRAWINGS

FIG. 1 is a schematic plan view showing a configuration of a display device including a semiconductor device according to an embodiment of the present invention.

FIG. 2 is a schematic diagram showing an equivalent circuit of a pixel including a semiconductor device according to an embodiment of the present invention.

FIG. 3 is a schematic cross-sectional view showing a configuration of a pixel including a semiconductor device according to an embodiment of the present invention.

FIG. 4 is a flowchart for explaining a method for manufacturing a pixel including a semiconductor device according to an embodiment of the present invention.

FIG. 5 is a schematic cross-sectional view showing a method for manufacturing a pixel including a semiconductor device according to an embodiment of the present invention.

FIG. 6 is a schematic cross-sectional view showing a method for manufacturing a pixel including a semiconductor device according to an embodiment of the present invention.

FIG. 7 is a schematic cross-sectional view showing a method for manufacturing a pixel including a semiconductor device according to an embodiment of the present invention.

FIG. 8 is a schematic cross-sectional view showing a method for manufacturing a pixel including a semiconductor device according to an embodiment of the present invention.

FIG. 9A is a schematic cross-sectional view showing a method for manufacturing a pixel including a semiconductor device according to an embodiment of the present invention.

FIG. 9B is a schematic cross-sectional view showing a method for manufacturing a pixel including a semiconductor device according to an embodiment of the present invention.

FIG. 10A is a schematic cross-sectional view showing a method for manufacturing a pixel including a semiconductor device according to an embodiment of the present invention.

FIG. 10B is a schematic cross-sectional view showing a method for manufacturing a pixel including a semiconductor device according to an embodiment of the present invention.

FIG. 10C is a schematic cross-sectional view showing a method for manufacturing a pixel including a semiconductor device according to an embodiment of the present invention.

FIG. 11 is a schematic cross-sectional view showing a method for manufacturing a pixel including a semiconductor device according to an embodiment of the present invention.

FIG. 12 is a schematic cross-sectional view showing a method for manufacturing a pixel including a semiconductor device according to an embodiment of the present invention.

FIG. 13 is a schematic cross-sectional view showing a method for manufacturing a pixel including a semiconductor device according to an embodiment of the present invention.

FIG. 14 is a schematic cross-sectional view showing a method for manufacturing a pixel including a semiconductor device according to an embodiment of the present invention.

FIG. 15 is a schematic cross-sectional view showing a method for manufacturing a pixel including a semiconductor device according to an embodiment of the present invention.

FIG. 16 is a schematic cross-sectional view showing a method for manufacturing a pixel including a semiconductor device according to an embodiment of the present invention.

FIG. 17 is a schematic cross-sectional view showing a method for manufacturing a pixel including a semiconductor device according to an embodiment of the present invention.

FIG. 18A is a schematic cross-sectional view showing a method for manufacturing a pixel including a semiconductor device according to an embodiment of the present invention.

FIG. 18B is a schematic cross-sectional view showing a method for manufacturing a pixel including a semiconductor device according to an embodiment of the present invention.

FIG. 19A is a schematic cross-sectional view showing a method for manufacturing a pixel including a semiconductor device according to an embodiment of the present invention.

FIG. 19B is a schematic cross-sectional view showing a method for manufacturing a pixel including a semiconductor device according to an embodiment of the present invention.

FIG. 20 is a schematic cross-sectional view showing a method for manufacturing a pixel including a semiconductor device according to an embodiment of the present invention.

FIG. 21 is a schematic cross-sectional view showing a method for manufacturing a pixel including a semiconductor device according to an embodiment of the present invention.

FIG. 22 is a schematic cross-sectional view showing a method for manufacturing a pixel including a semiconductor device according to an embodiment of the present invention.

FIG. 23 is a schematic cross-sectional view showing a method for manufacturing a pixel including a semiconductor device according to an embodiment of the present invention.

FIG. 24 is a schematic cross-sectional view showing a method for manufacturing a pixel including a semiconductor device according to an embodiment of the present invention.

FIG. 25 is a schematic cross-sectional view showing a method for manufacturing a pixel including a semiconductor device according to an embodiment of the present invention.

FIG. 26 is a schematic cross-sectional view showing a method for manufacturing a pixel including a semiconductor device according to an embodiment of the present invention.

FIG. 27 is a schematic cross-sectional view showing a method for manufacturing a pixel including a semiconductor device according to an embodiment of the present invention.

FIG. 28 is a schematic cross-sectional view showing a method for manufacturing a pixel including a semiconductor device according to an embodiment of the present invention.

FIG. 29 is a schematic cross-sectional view showing a method for manufacturing a pixel including a semiconductor device according to an embodiment of the present invention.

FIG. 30 is a schematic cross-sectional view showing a method for manufacturing a pixel including a semiconductor device according to a modification of an embodiment of the present invention.

FIG. 31 is a schematic cross-sectional view showing a method for manufacturing a pixel including a semiconductor device according to a modification of an embodiment of the present invention.

FIG. 32 is a schematic cross-sectional view showing a method for manufacturing a pixel including a semiconductor device according to a modification of an embodiment of the present invention.

FIG. 33 is a schematic cross-sectional view showing a method for manufacturing a pixel including a semiconductor device according to a modification of an embodiment of the present invention.

FIG. 34 is a schematic cross-sectional view showing a method for manufacturing a pixel including a semiconductor device according to a modification of an embodiment of the present invention.

### DESCRIPTION OF EMBODIMENTS

A transistor using an oxide semiconductor layer as a channel often suffers from degradation of electrical characteristics due to a decrease in channel resistance. For example, if hydrogen is excessively diffused into an oxide semiconductor forming a channel, the channel resistance decreases, and the transistor unintentionally operates in a depletion mode.

An object of an embodiment of the present invention is to suppress the decrease in channel resistance of a semiconductor device using an oxide semiconductor.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. For clarity of explanation, the drawings may be schematically represented with respect to widths, thicknesses, shapes, and the like of components in comparison with actual embodiments. However, the illustrated shapes are merely examples, and do not limit the interpretation of the present invention. In the present specification, the claims, and the drawings (hereinafter, referred to as “the present specification and the like”), the same components as those described above with respect to the above-described drawings are denoted by the same reference signs, and the detailed description thereof may be omitted as appropriate.

In the present specification and the like, a direction from a substrate toward an oxide semiconductor layer is referred to as “on” or “above”. Conversely, a direction from the oxide semiconductor layer to the substrate is referred to as “under” or “below”. As described above, for convenience of explanation, although the phrase “above” or “below” is used for description, for example, the vertical relationship between the substrate and the oxide semiconductor layer may be different from the drawings. In addition, the expression “an oxide semiconductor layer on a substrate” merely describes the vertical relationship between the substrate and the oxide semiconductor layer, and another component may be arranged between the substrate and the oxide semiconductor layer. “Above” or “below” means a stacking order in a structure in which a plurality of layers is stacked, and when expressed as a pixel electrode above the semiconductor device, it may be a positional relationship in which the semiconductor device and the pixel electrode do not overlap in a plan view. On the other hand, when expressed as a pixel electrode vertically above the semiconductor device, it means a positional relationship in which the semiconductor device and the pixel electrode overlap in a plan view. In addition, a plan view refers to a view from a direction perpendicular to a surface of the substrate.

In the present specification and the like, a plurality of elements formed by subjecting a certain film to a process such as etching may be described as elements having different functions or roles. These elements are composed of the same layer structure and the same material, and are described as elements composed of the same layer. That is, in the present specification and the like, when “A and B are the same layer”, it means that both the element A and the element B are elements formed by processing a single layer.

In the present specification and the like, the expression “α includes A, B, or C”, “α includes any of A, B, and C”, and “α includes one selected from a group consisting of A, B, and C” does not exclude the case where α includes a plurality of combinations of A to C unless otherwise specified. Furthermore, these expressions do not exclude the case where α includes other components.

In the present specification and the like, the term “semiconductor device” refers to any device that can function by utilizing semiconductor properties. A transistor and a semiconductor circuit are included in one form of the semiconductor device. For example, the semiconductor device of the embodiments described below can be used in an Integrated Circuit (IC) such as a display device or a Micro-Processing Unit (MPU), or in a memory circuit.

In the present specification and the like, the term “display device” refers to a structure that displays an image using an electro-optical layer. For example, the term “display device” may refer to a display panel including the electro-optical layer, or may refer to a structure with other optical members (e.g., polarized member, backlight, touch panel, etc.) attached to a display cell. The “electro-optical layer” may include a liquid crystal layer, an electroluminescent (EL) layer, an electrochromic (EC) layer, and an electrophoretic layer, as long as there is no technical contradiction. Therefore, with respect to the embodiment to be described later, although a display device will be described by exemplifying an organic EL display device containing an organic EL layer, the structure in the present embodiment can be applied to a display device containing the other electro-optical layers described above.

In the present specification and the like, the terms “film” and “layer” can optionally be interchanged with each another.

The functions of a source and a drain of the transistor may be switched depending on a voltage supplied to each. Therefore, in the present specification and the like, the term “source” and the term “drain”may be interchanged with each other.

In addition, the following embodiments can be combined with each other as long as there is no technical contradiction.

### First Embodiment

### Configuration of Display Device

Hereinafter, a display device 10 according to an embodiment of the present invention will be described. In the present embodiment, an organic EL display device is exemplified as the display device 10. The organic EL display device is a display device including an organic EL element as a light-emitting element and a semiconductor device for driving the light-emitting element.

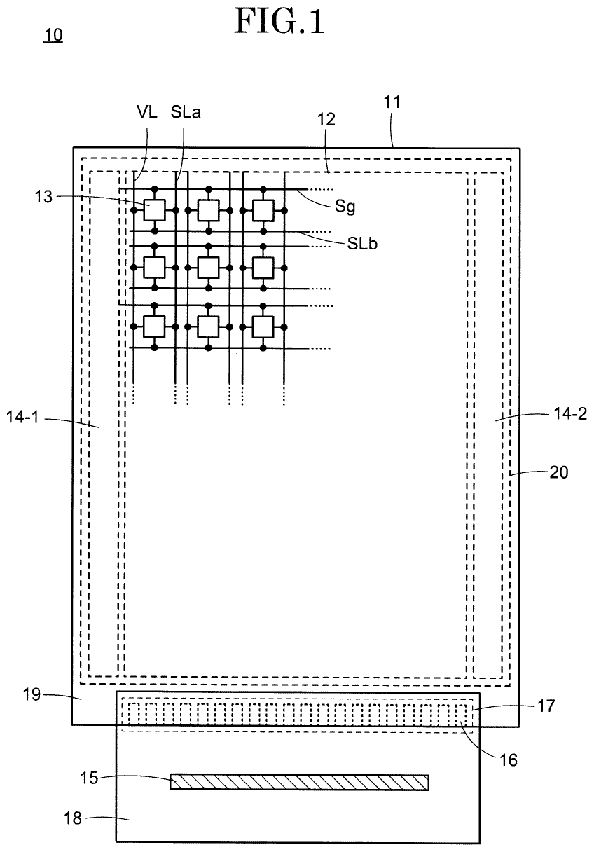

FIG. 1 is a schematic plan view showing a configuration of the display device 10 including a semiconductor device according to an embodiment of the present invention. As shown in FIG. 1, the display device 10 includes a display part 12 and a peripheral part 19 provided on a substrate 11. The display part 12 includes a plurality of pixels 13 arranged in a matrix. Each of the plurality of pixels 13 includes a semiconductor device and a light-emitting element formed of a plurality of transistors described later. A touch sensor 20 is arranged in the display part 12 and on the display part 12.

The peripheral part 19 is provided to surround the display part 12. The peripheral part 19 refers to the part of the substrate 11 from the display part 12 to the end portion of the substrate 11. In other words, the peripheral part 19 refers to a part other than the part where the display part 12 is provided on the substrate 11 (specifically, a part outside the display part 12). The peripheral part 19 includes gate drive circuits 14-1 and 14-2 and a terminal part 17 including a plurality of terminals 16. The gate drive circuits 14-1 and 14-2 are provided so as to sandwich the display part 12. A flexible printed circuit 18 on which a driver IC 15 is mounted is connected to the terminal part 17. A plurality of wirings (not shown) included in the flexible printed circuit 18 is connected to the driver IC 15 and the terminal part 17. In the example shown in FIG. 1, a source drive circuit is integrated into the driver IC 15. However, the present invention is not limited to this example, and the source drive circuit may be formed on the substrate 11 using a transistor.

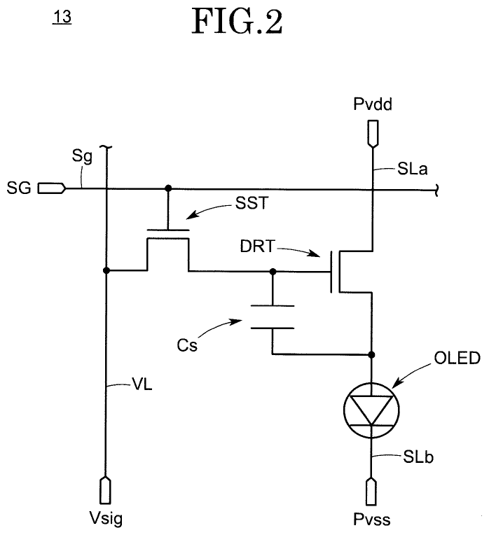

The driver IC 15 is connected to the gate drive circuits 14-1 and 14-2 and a plurality of video signal lines VL. The gate drive circuit 14-1 or the gate drive circuit 14-2 is connected to a pixel 13 via a selection control line Sg. For example, among the plurality of selection control lines Sg, the selection control line Sg of an odd-numbered row is connected to the gate drive circuit 14-1, and the selection control line Sg of an even-numbered row is connected to the gate drive circuit 14-2. The video signal line VL is connected to the pixel 13. A control signal SG (see FIG. 2) for selecting each pixel 13 is supplied from the driver IC 15 to the display part 12 via the gate drive circuits 14-1 and 14-2 and the selection control line Sg. In addition, a video signal Vsig (see FIG. 2) is supplied from the driver IC 15 to the display part 12 via the video signal line VL. With these signals, the plurality of transistors included in the pixel 13 can be driven, and an image according to the video signal Vsig can be displayed on the display part 12. A high potential power line SLa and a low potential power line SLb connected to the pixel 13 are connected to different terminals 16, respectively.

A glass substrate, a quartz substrate, a ceramic substrate, a plastic substrate having flexibility, or a resin substrate can be used as the substrate 11. In the case where the plastic substrate or resin substrate having flexibility is used as the substrate 11, the substrate 11 can be bent between the display part 12 and the terminal part 17. This makes it possible to reduce the area of the bezel part of the display device 10.

### Configuration of Pixel Circuit

FIG. 2 is a schematic circuit diagram showing a circuit configuration of the pixel 13 including a semiconductor device according to an embodiment of the present invention. The high potential power line SLa, the low potential power line SLb, the selection control line Sg, and the video signal line VL are connected to each pixel 13 forming the display device 10. The high potential power line SLa is connected to a high potential power source Pvdd. The low potential power line SLb is connected to a low potential power source Pvss. The selection control line Sg is connected to the gate drive circuits 14-1 and 14-2. The video signal line VL is connected to the driver IC 15 that supplies the video signal Vsig.

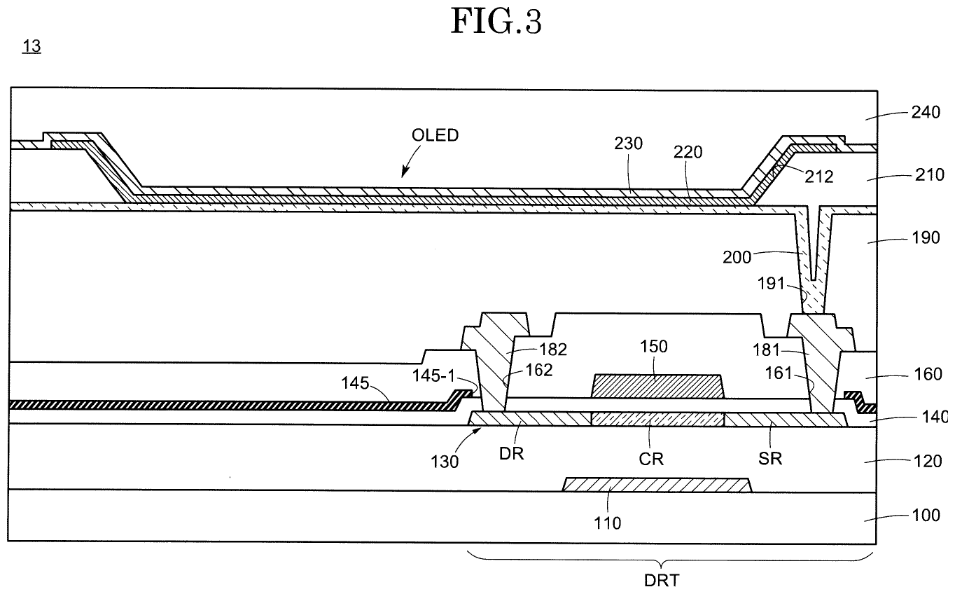

Each pixel 13 includes at least a drive transistor DRT, a select transistor SST, and a light-emitting element OLED. The high potential power source Pvdd is connected to an anode of the light-emitting element OLED via the drive transistor DRT. The low potential power source Pvss is connected to a cathode of the light-emitting element OLED. In the present embodiment, the anode of the light-emitting element OLED is connected to a pixel electrode 200 (see FIG. 3) and the cathode is connected to a common electrode 230 (see FIG. 3).

The drive transistor DRT is connected in series with the light-emitting element OLED between the high potential power line SLa and the low potential power line SLb. The drive transistor DRT functions as a current control element that controls a current value flowing through the light-emitting element OLED according to a gate-source voltage. The select transistor SST functions as a switching element to select conduction or non-conduction between two nodes, and applies a voltage corresponding to the luminance of the light-emitting element OLED to a gate of the drive transistor DRT. A storage capacitor Cs is provided between the gate-source of the drive transistor DRT. The storage capacitor Cs holds the gate-source voltage of the drive transistor DRT.

The gate of the select transistor SST is connected to the selection control line Sg, one of the source or the drain is connected to the video signal line VL, and the other of the source or the drain is connected to the gate of the drive transistor DRT and the storage capacitor Cs. The drain of the drive transistor DRT is connected to the high potential power line SLa and the source is connected to the storage capacitor Cs and the light-emitting element OLED. The cathode of the light-emitting element OLED is connected to the low potential power line SLb. The drive transistor DRT outputs a driving current corresponding to the video signal Vsig to the light-emitting element OLED.

Although not shown in the diagram, the pixel 13 may further include other transistors such as a correct transistor that corrects a threshold value of the drive transistor DRT and a reset transistor that resets a voltage held in the storage capacitor Cs.

In the present embodiment, an oxide semiconductor is used as the semiconductor used for the select transistor SST and the drive transistor DRT. Since the transistor using the oxide semiconductor has a low off-leakage current and can be driven at a low frequency, the transistor has an advantage of low power consumption. Therefore, by forming the pixel using the oxide semiconductor, it is possible to reduce the power consumption of the display device 10. Further, the transistor using the oxide semiconductor also has an advantage that the kink-effect is not observed and the saturation characteristics are better than those of the transistor using so-called low-temperature polysilicon.

### Pixel Structure

FIG. 3 is a schematic cross-sectional view showing a configuration of the pixel 13 including a semiconductor device according to an embodiment of the present invention. In the pixel 13 shown in FIG. 3, the drive transistor DRT that supplies a current to the light-emitting element OLED is illustrated as the semiconductor device. Although not shown in FIG. 3, the pixel 13 includes the select transistor SST shown in FIG. 2. The pixel 13 shown in FIG. 3 may include more transistors in addition to the drive transistor DRT and the select transistor SST.

The drive transistor DRT of the present embodiment includes a conductive layer 110, an insulating layer 120, an oxide semiconductor layer 130, an insulating layer 140, a metal oxide layer 145, a conductive layer 150, an insulating layer 160, a conductive layer 181, and a conductive layer 182 arranged on a substrate 100 having an insulating surface.

For example, the substrate 100 is a glass substrate on which one or more insulating layers composed of an insulating oxide such as silicon oxide (SiOₓ) or silicon oxynitride (SiOₓN_{y}) or an insulating nitride such as silicon nitride (SiNₓ) or silicon nitride oxide (SiNₓO_{y}) are formed. In this case, the silicon nitride oxide (SiNₓO_{y}) is a silicon oxide containing a smaller proportion (x>y) of oxygen than nitrogen. The silicon oxynitride (SiOₓN_{y}) is a silicon nitride containing a smaller proportion (x>y) of nitrogen (N) than oxygen (O).

In the present embodiment, the substrate 100 having an insulating surface is formed by stacking a silicon nitride layer and a silicon oxide layer on the glass substrate in this order from the bottom. The silicon nitride layer serves as a protective layer that prevents the intrusion of contaminants (e.g., alkaline substances) from the glass substrate. However, the present invention is not limited to this example, a quartz substrate, a ceramic substrate, a plastic substrate, or a resin substrate may be used instead of the glass substrate. In addition, the silicon oxide layer, the silicon nitride layer, the silicon oxynitride layer, and the silicon nitride oxide layer may be stacked in any order.

The conductive layer 110 is provided on the substrate 100. The conductive layer 110 functions as a lower-side gate electrode in the drive transistor DRT. Aluminum (Al), copper (Cu), titanium (Ti), molybdenum (Mo), tantalum (Ta), tungsten (W), or an alloy thereof can be used as a material for forming the conductive layer 110. In the present embodiment, a molybdenum-tungsten alloy is used as a material for forming the conductive layer 110. The conductive layer 110 also functions as a light-shielding layer that reduces the light reaching the oxide semiconductor layer 130 from the lower layer side.

The insulating layer 120 is provided on the conductive layer 110. The insulating layer 120 functions as a lower-side gate insulating layer in the drive transistor DRT. One or more layers selected from a silicon oxide layer, a silicon nitride layer, a silicon oxynitride layer, or a silicon nitride oxide layer can be used as the insulating layer 120. In the present embodiment, an insulating layer in which a silicon nitride layer and a silicon oxide layer are stacked in this order from the bottom is used as the insulating layer 120. As will be described later, since the oxide semiconductor layer 130 is provided on the insulating layer 120, the surface of the insulating layer 120 in contact with the oxide semiconductor layer 130 is preferably a silicon oxide layer.

A thickness of the insulating layer 120 is not particularly limited. In the present embodiment, the thickness of the insulating layer 120 is set to be 200 nm or more and 600 nm or less (preferably 300 nm or more and 500 nm or less, more preferably 350 nm or more and 450 nm or less). In the present embodiment, a stacked structure formed of a silicon nitride layer having a thickness of 100 nm and a silicon oxide layer having a thickness of 200 nm is used as the insulating layer 120.

The oxide semiconductor layer 130 is provided on the insulating layer 120. The oxide semiconductor layer 130 functions as an active layer in the drive transistor DRT. An amorphous oxide semiconductor (e.g., IGZO) can be used as a material for forming the oxide semiconductor layer 130. A thickness of the oxide semiconductor layer 130 may be 10 nm or more and 100 nm or less (preferably 15 nm or more and 70 nm or less, more preferably 15 nm or more and 40 nm or less).

In the present embodiment, the oxide semiconductor layer 130 can be formed using a sputtering method. The composition of the oxide semiconductor layer 130 formed using the sputtering method depends on the composition of the sputtering target.

In addition, as shown in FIG. 3, the oxide semiconductor layer 130 is divided into a channel region CR, a source region SR, and a drain region DR. The channel region CR is a region that overlaps the conductive layer 150 functioning as the gate electrode, and forms a channel when a gate voltage is applied to the conductive layer 150. The source region SR and the drain region DR are regions with a lower resistance than the channel region CR and function as a conductive region. That is, the source region SR and the drain region DR have higher electrical conductivity than the channel region CR. In other words, the source region SR and the drain region DR have properties as a conductor, and the channel region has properties as a semiconductor. As will be described later, the source region SR and the drain region DR are formed by adding an impurity to the oxide semiconductor layer 130 using a method such as ion-implantation.

The insulating layer 140 is provided on the oxide semiconductor layer 130. The insulating layer 140 functions as an upper-side gate insulating layer in the drive transistor DRT. One or more layers selected from a silicon oxide layer, a silicon nitride layer, a silicon oxynitride layer, or a silicon nitride oxide layer can be used as the insulating layer 140. In the present embodiment, a silicon oxide layer is used as the insulating layer 140. Preferably, the insulating layer 140 has few defects and a composition close to the stoichiometric ratio. Specifically, the insulating layer 140 is preferably free of defects when evaluated by an Electron Spin Resonance (ESR) method. A thickness of the insulating layer 140 is not particularly limited. In the present embodiment, the thickness of the insulating layer 140 is set to be 50 nm or more and 300 nm or less (preferably 60 nm or more and 200 nm or less, more preferably 70 nm or more and 150 nm or less).

The metal oxide layer 145 is a layer composed of an oxide insulator containing a metal, and is formed by the sputtering method as described later. In the present embodiment, a metal oxide containing aluminum as a main component is used as the metal oxide layer 145. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide layer 145. The expression “metal oxide layer containing aluminum as a main component” means that the proportion of aluminum contained in the metal oxide layer 145 is 1% or more of the entire metal oxide layer 145. The proportion of aluminum contained in the metal oxide layer 145 may be 5% or more and 70% or less, 10% or more and 60% or less, or 30% or more and 50% or less of the entire metal oxide layer 145. The ratio may be a mass ratio or a weight ratio. In the present embodiment, a thickness of the metal oxide layer 145 is 20 nm or less (preferably 15 nm or less, more preferably 10 nm or less).

In the present embodiment, the metal oxide layer 145 has an opening 145-1. As will be described later, the opening 145-1 is provided to overlap at least a part of the oxide semiconductor layer 130. That is, with respect to the metal oxide layer 145, the opening 145-1 is provided so that all or substantially all of the oxide semiconductor layer 130 is exposed (that is, the metal oxide layer 145 and the oxide semiconductor layer 130 do not overlap each other) in a plan view. Therefore, the metal oxide layer 145 can also be referred to as a metal oxide pattern.

The conductive layer 150 is provided on the insulating layer 140. The conductive layer 150 functions as an upper-side gate electrode in the drive transistor DRT. Aluminum (Al), copper (Cu), titanium (Ti), molybdenum (Mo), tantalum (Ta), tungsten (W), or an alloy thereof can be used as a material for forming the conductive layer 150. In the present embodiment, a molybdenum-tungsten alloy is used as a material for forming the conductive layer 150. The conductive layer 150 also functions as a light-shielding layer that reduces the light reaching the oxide semiconductor layer 130 from the upper side.

As described above, the conductive layer 150 functions as the upper-side gate electrode in the drive transistor DRT, but also functions as a gate wiring. In other words, the conductive layer 150 functions as the gate wiring, and a part of the gate wiring that overlaps the oxide semiconductor layer functioning as the active layer of the transistor functions as the gate electrode. Therefore, although the gate electrode and the gate wiring may be separately described in the present specification for convenience of explanation, both of them may be an integral member.

The insulating layer 160 is provided on the conductive layer 150. The insulating layer 160 functions as an interlayer insulating layer in the drive transistor DRT. One or more layers selected from a silicon oxide layer, a silicon nitride layer, a silicon oxynitride layer, or a silicon nitride oxide layer can be used as the insulating layer 160. In the present embodiment, a stacked structure including a silicon oxide layer and a silicon nitride layer is used as the insulating layer 160.

The conductive layers 181 and 182 are provided on the insulating layer 160. The conductive layer 181 is connected to the source region SR of the oxide semiconductor layer 130 via a contact hole 161 provided in the insulating layer 160, and functions as a source electrode in the drive transistor DRT. The conductive layer 182 is connected to the drain region DR of the oxide semiconductor layer 130 via a contact hole 162 provided in the insulating layer 160, and functions as a drain electrode in the drive transistor DRT. In other words, the conductive layers 181 and 182 function as terminal electrodes in the drive transistor DRT, respectively.

Aluminum (Al), copper (Cu), titanium (Ti), molybdenum (Mo), tantalum (Ta), tungsten (W), or an alloy thereof can be used as a material for forming the conductive layers 181 and 182. In the present embodiment, a stacked structure including a titanium layer and an aluminum layer can be used as a material for forming the conductive layers 181 and 182.

As described above, the drive transistor DRT of the present embodiment is a dual-gate transistor including a lower-side gate electrode (the conductive layer 110) opposed to the oxide semiconductor layer 130 via the insulating layer 120, and an upper-side gate electrode (the conductive layer 150) opposed to the oxide semiconductor layer 130 via the insulating layer 140. However, the present invention is not limited to this example, and the drive transistor DRT may be a top-gate transistor. For example, in the case where the conductive layer 110 is not used as the gate electrode, such as by applying a fixed voltage to the conductive layer 110 shown in FIG. 3, the drive transistor DRT functions as a top-gate transistor.

An insulating layer 190 is provided on the drive transistor DRT as a planarization layer composed of a resin material. The pixel electrode 200 is connected to the conductive layer 181 (that is, the source electrode of the drive transistor DRT) via a contact hole 191 provided in the insulating layer 190. In the present embodiment, a stacked structure of a layer containing silver (Ag) and a layer containing a metal oxide (for example, ITO) is used as the pixel electrode 200, but the present invention is not limited to this example.

A bank 210 composed of a resin material is provided on the pixel electrode 200. The bank is also referred to as a partition or rib. The bank 210 is provided to cover a part of the pixel electrode 200. In other words, the bank 210 has an opening 212 at a position overlapping the pixel electrode 200. A region of the pixel electrode 200 that is not covered with the bank 210 (that is, exposed region) functions as a light-emitting region of the pixel 13. A light-emitting layer 220 composed of an organic EL (electroluminescence) material is provided to cover the exposed region of the pixel electrode 200.

Further, the common electrode 230 is provided to cover the bank 210 and the light-emitting layer 220. Although not shown in FIG. 3, the common electrode 230 is arranged across the plurality of pixels 13. The pixel electrode 200, the light-emitting layer 220, and the common electrode 230 form the light-emitting element OLED. The pixel electrode 200 functions as the anode of the light-emitting element OLED. The common electrode 230 functions as the cathode of the light-emitting element OLED.

A sealing layer 240 is provided on the light-emitting element OLED. The sealing layer 240 is a protective layer for preventing intrusion of moisture or the like from the outside. In the present embodiment, a stacked structure in which an inorganic insulating layer, an organic insulating layer, and an inorganic insulating layer are stacked in this order from the lower layer is used as the sealing layer 240. For example, a silicon nitride layer can be used as the inorganic insulating layer. For example, an organic resin layer (for example, a resin layer composed of polyimide or acryl) can be used as the organic insulating layer.

As described above, the drive transistor DRT is provided in the pixel 13, and there is a characteristic impurity-distribution around the drive transistor DRT in relation to the manufacturing method described later. This point will be described in detail together with the method for manufacturing the semiconductor device described below.

### Method for Manufacturing Pixel

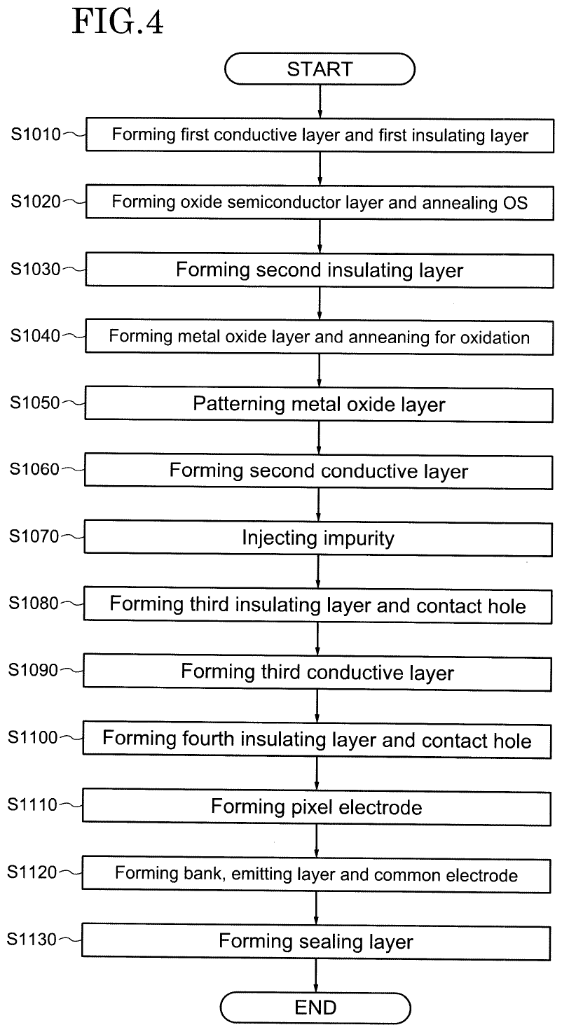

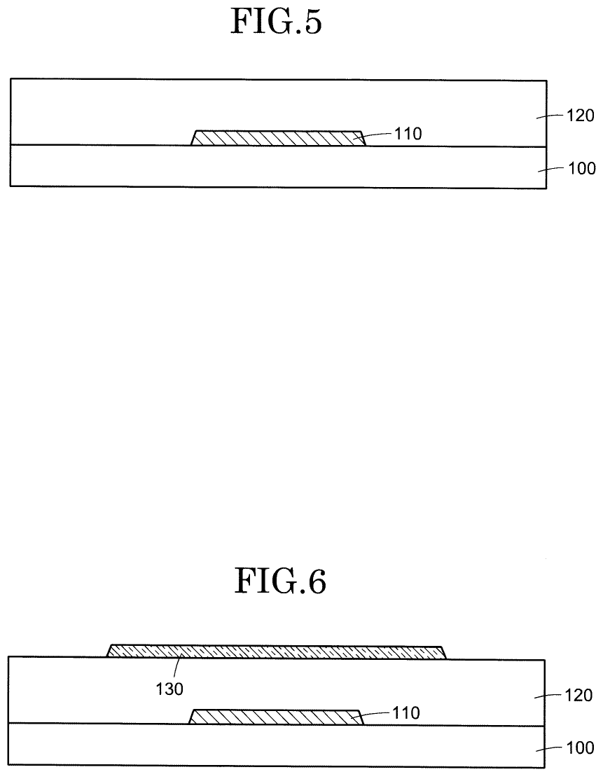

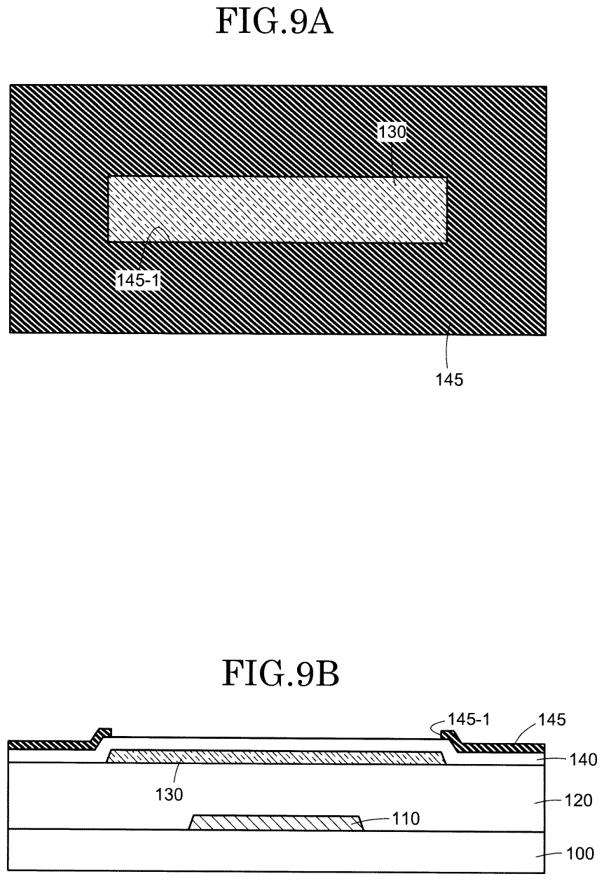

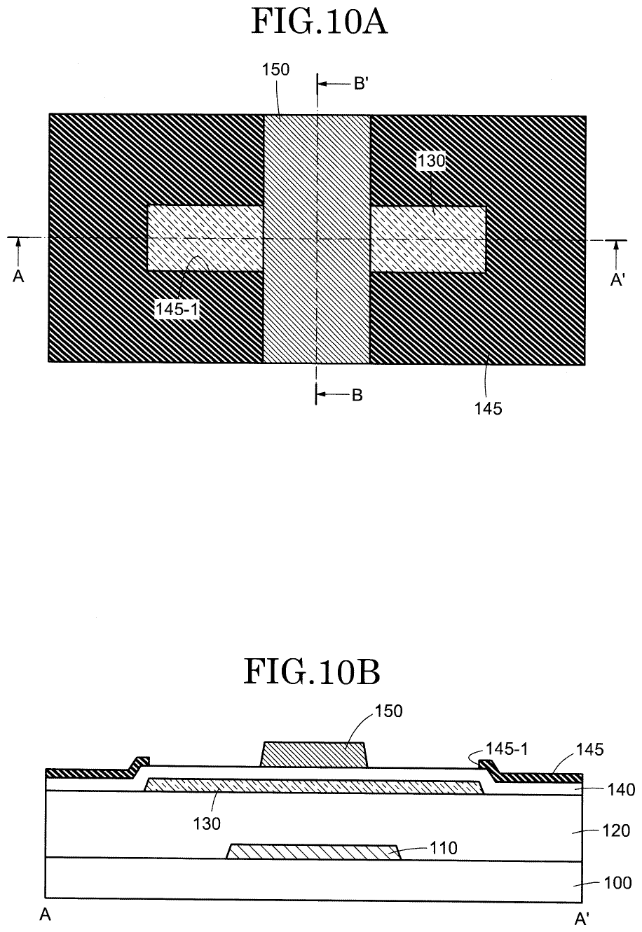

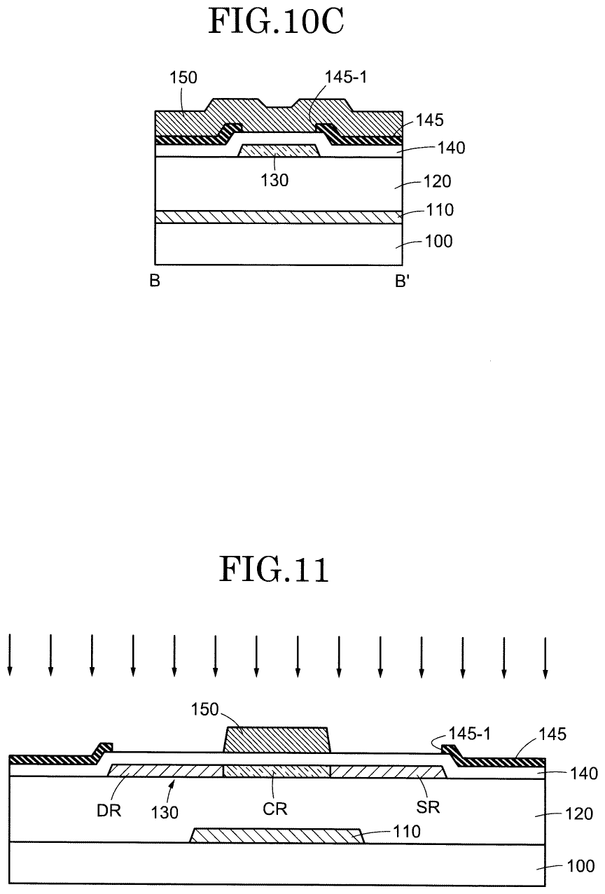

FIG. 4 is a flowchart for explaining a method for manufacturing the pixel 13 including a semiconductor device according to an embodiment of the present invention. FIG. 5 to FIG. 8, FIG. 9B, FIG. 10B, FIG. 10C, and FIG. 11 to FIG. 17 are schematic cross-sectional views showing a method for manufacturing the pixel 13 including the semiconductor device according to an embodiment of the present invention. FIG. 9A and FIG. 10A are schematic plan views showing a method for manufacturing the pixel 13 including the semiconductor device according to an embodiment of the present invention. As shown in FIG. 4, the method for manufacturing the semiconductor device of the present embodiment includes step S1010 to step S1130. Hereinafter, the step S1010 to the step S1130 will be described in order, but the order of the steps may be changed in the method for manufacturing the semiconductor device of the present embodiment. Further, in the method for manufacturing the semiconductor device of the present embodiment, one or a plurality of steps may be omitted, or further steps may be included.

First, as shown in FIG. 4 and FIG. 5, the conductive layer 110 (first conductive layer) having a predetermined pattern-shape is formed on the substrate 100 (step S1010). The patterning of the conductive layer 110 is performed using photolithography. In the present embodiment, the conductive layer 110 functions as a light-shielding layer. In addition, the insulating layer 120 (first insulating layer) is formed to cover the conductive layer 110. The insulating layer 120 is deposited using a chemical vapor deposition (CVD) method. In the present embodiment, a stacked structure formed of a silicon nitride layer having a thickness of 100 nm and a silicon oxide layer having a thickness of 200 nm is used as the insulating layer 120.

Next, as shown in FIG. 4 and FIG. 6, the oxide semiconductor layer 130 having a predetermined pattern-shape is formed on the insulating layer 120 (step S1030). The oxide semiconductor layer 130 is formed to overlap the conductive layer 110. The oxide semiconductor layer 130 is formed by patterning an oxide semiconductor film deposited by the sputtering method into a predetermined shape using photolithography. The oxide semiconductor film deposited using the sputtering method has an amorphous structure.

The oxide semiconductor film having the amorphous structure can be easily patterned using photolithography. When the oxide semiconductor film is etched, either wet etching or dry etching may be used. In the case where wet etching is used, the oxide semiconductor film can be etched using an acid etching solution. For example, an oxalic acid solution, a PAN (mixed acid of phosphoric acid, nitric acid, and acetic acid), a sulfuric acid solution, a hydrogen peroxide solution, or a hydrofluoric acid solution can be used as the etching solution.

In addition, a heat treatment is performed on the oxide semiconductor layer 130 having a predetermined pattern-shape. Hereinafter, the heat treatment performed in the step S1020 is referred to as “annealing OS”. In the “annealing OS” process, the oxide semiconductor layer 130 is held at a predetermined reaching temperature for a predetermined time. The predetermined reaching temperature is 300° C. or higher and 500° C. or lower (preferably 350° C. or higher and 450° C. or lower). In addition, the holding time at the reaching temperature is 15 minutes or more and 120 minutes or less (preferably 30 minutes or more and 60 minutes or less).

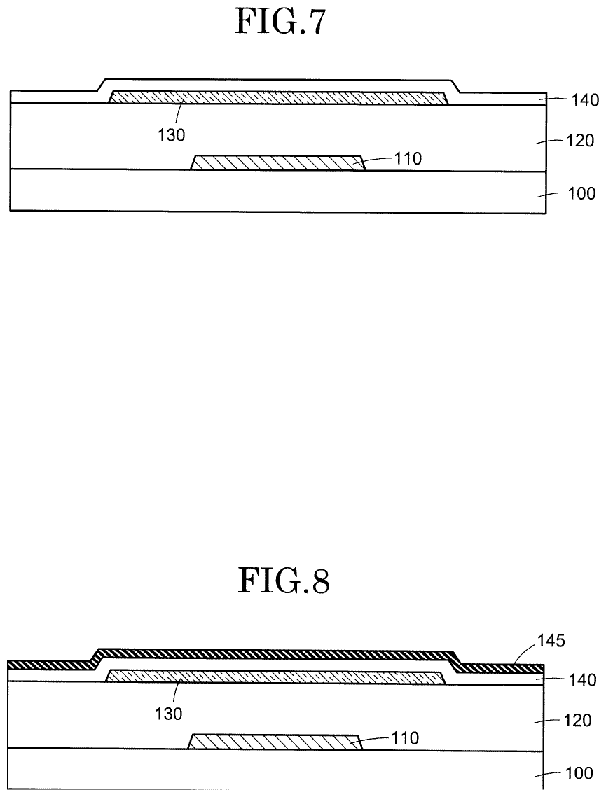

Next, as shown in FIG. 4 and FIG. 7, the insulating layer 140 (second insulating layer) is formed on the oxide semiconductor layer 130 (step S1030). In the present embodiment, the silicon oxide layer having a thickness of 100 nm is used as the insulating layer 140. Further, the heat treatment is performed on the insulating layer 140.

Next, as shown in FIG. 4 and FIG. 8, the metal oxide layer 145 is formed on the insulating layer 140 (step S1040). In the present embodiment, an aluminum oxide (AlOₓ) layer having a thickness of 8 nm is formed as the metal oxide layer 145 by the sputtering method. When the metal oxide layer 145 is formed by the sputtering method, a large amount of oxygen is implanted into the insulating layer 140. The metal oxide layer 145 at this stage is a metal oxide layer (metal oxide layer in a deposited state) without being subjected to a patterning process.

In addition, a heat treatment is performed on the oxide semiconductor layer 140. Hereinafter, the heat treatment performed in the step S1040 is referred to as “annealing OS”. Due to the formation of the oxide semiconductor layer 130 and the formation of the insulating layer 140, many oxygen defects are generated inside the oxide semiconductor layer 130. When the annealing for oxidation process is performed, oxygen is supplied from the insulating layer 140 to the oxide semiconductor layer 130, and the oxygen defects in the oxide semiconductor layer 130 are repaired. The formation of oxide semiconductor layers 130 and the formation of insulating layer 140 create a number of oxygen-deficiencies within oxide semiconductor layers 130. In the present embodiment, oxygen is injected into the insulating layer 140, and then the amount of oxygen inside the insulating layer 140 at the time of forming the aluminum oxide layer is increased, so that a sufficient amount of oxygen can be supplied to the oxide semiconductor layer 130 by the annealing for oxidation process. Further, at this time, since the metal oxide layer 145 functions as a barrier layer that prevents oxygen from moving, oxygen can be efficiently supplied to the oxide semiconductor layer 130.

Next, as shown in FIG. 4, FIG. 9A, and FIG. 9B, the metal oxide layer 145 is patterned to form the opening 145-1 (step S1050). In the present embodiment, a resist mask (not shown) is formed on the metal oxide layer 145 by photolithography, and the metal oxide layer 145 is etched by a wet etching process using a hydrofluoric acid solution to form the opening 145-1. The metal oxide layer 145 at this stage is a processed metal oxide layer that has been subjected to a patterning process (a patterned metal oxide layer).

As shown in FIG. 9A, the metal oxide layer 145 is formed in a region that does not overlap the oxide semiconductor layer 130. Specifically, the position of the inner wall of the opening 145-1 and the position of the end portion of the oxide semiconductor layer 130 coincide with each other in a direction perpendicular to the substrate 100. In other words, as shown in FIG. 9A and FIG. 9B, in a plan view, the outer shape of the edge of the opening 145-1 provided in the metal oxide layer 145 coincides with the outer shape of the edge of the oxide semiconductor layer 130.

In this case, “coincide” includes not only the case of perfect coincidence, but also the case of falling within a range of an error in the alignment when forming the opening 145-1. For example, even if the position of the outer shape of the edge of the opening 145-1 and the position of the outer shape of the edge of the oxide semiconductor layer 130 are different within a range of 1.5 μm (preferably 1.0 μm, more preferably 0.5 μm), it is considered that the outer shape of the edge of the opening 145-1 and the outer shape of the edge of the oxide semiconductor layer 130 coincide with each other.

Strictly speaking, although FIG. 9B shows an example in which the position of the inner wall of the opening 145-1 and the position of the end portion on the upper surface of the oxide semiconductor layer 130 coincide with each other in the direction perpendicular to the substrate 100, the position of the inner wall of the opening 145-1 and the position of the end portion on the lower surface of the oxide semiconductor layer 130 may coincide with each other in the direction perpendicular to the substrate 100.

Next, as shown in FIG. 4, FIG. 10A, FIG. 10B, and FIG. 10C, the conductive layer 150 (second conductive layer) is formed on the insulating layer 140 and the metal oxide layer 145 (step S1060). In the present embodiment, the conductive layer 150 functions as a gate wiring. In the present embodiment, the conductive layer 150 is formed by forming a metal film composed of a molybdenum-tungsten alloy using the sputtering method and patterning the metal film into a predetermined shape. In the present embodiment, the thickness of the conductive layer 150 is 300 nm, but the present invention is not limited to this example.

As shown in FIG. 10A, the conductive layer 150 is formed to intersect the oxide semiconductor layer 130. Specifically, the conductive layer 150 has a longitudinal direction in a direction intersecting the longitudinal direction (channel direction) of the oxide semiconductor layer 130. In FIG. 10A, a cross-sectional view cut along a dashed-dotted line indicated by A-A′ corresponds to FIG. 10B, and a cross-sectional view cut along a dashed-dotted line indicated by B-B′ corresponds to FIG. 10C.

As shown in FIG. 10B, the oxide semiconductor layer 130 and the conductive layer 150 face each other via the insulating layer 140 in a region where the oxide semiconductor layer 130 and the conductive layer 150 overlap each other. The region where the oxide semiconductor layer 130 and the conductive layer 150 overlap is positioned inside the opening 145-1 provided in the metal oxide layer 145. Therefore, the conductive layer 150 and the insulating layer 140 are in contact with each other in the region where the conductive layer 150 and the oxide semiconductor layer 130 overlap each other.

As shown in FIG. 10C, the metal oxide layer 145 is arranged between the insulating layer 140 and the conductive layer 150 in the region where the oxide semiconductor layer 130 and the conductive layer 150 do not overlap each other. That is, the conductive layer 150 and the metal oxide layer 145 are in contact with each other in the region where the oxide semiconductor layer 130 and the conductive layer 150 do not overlap each other. As described above, since the periphery of the oxide semiconductor layer 130 is covered with the metal oxide layer 145, a large amount of oxygen remains in the insulating layer 140 positioned in the region covered with the metal oxide layer 145. As a result, as will be described later, the amount of hydrogen diffusing from the periphery of the oxide semiconductor layer 130 toward the oxide semiconductor layer 130 can be suppressed.

Next, as shown in FIG. 4 and FIG. 11, an impurity is injected into the oxide semiconductor layer 130 via the insulating layer 140 (step S1070). For example, the impurity can be injected into the oxide semiconductor layer 130 using the ion-implantation method. For example, argon (Ar), phosphorus (P), or boron (B) can be used as the impurity. However, the present invention is not limited to this example, and other elements may be used.

In the present embodiment, since the conductive layer 150 is formed on the oxide semiconductor layer 130, the conductive layer 150 functions as a mask, and the injection of impurities into a part of the oxide semiconductor layer 130 is inhibited. Therefore, in the oxide semiconductor layer 130, impurities are not injected into the region that overlaps the conductive layer 150, and the channel region CR is formed in that region. Further, the source region SR and the drain region DR are formed in the region of the oxide semiconductor layer 130 that does not overlap the conductive layer 150 and where the impurities are injected. In the source region SR and the drain region DR, oxygen defects are generated inside the oxide semiconductor layer 130 by the injection of impurities, and hydrogen is trapped in the oxygen defects. As a result, the source region SR and the drain region DR are electrically conductive and have higher electrical conductivity than the channel region CR.

In this case, the technical significance of arranging the metal oxide layer 145 in the present embodiment will be described. In the present embodiment, impurities are injected into the oxide semiconductor layer 130 via the insulating layer 140. In this case, in the present embodiment, since the silicon oxide layer is used as the insulating layer 140, Si—O bonds and Si—H bonds included in the silicon oxide layer may be cut by colliding with the impurities. As a result, oxygen and hydrogen are generated in a region of the insulating layer 140 through which impurities pass during the ion-implantation. In particular, the generated hydrogen easily moves inside the insulating layer 140 when heat is applied in a later process. Such hydrogen-diffusion may cause, for example, a decrease in resistance of the channel region CR (i.e., the decrease in channel resistance).

Therefore, in the present embodiment, a configuration is adopted in which the metal oxide layer 145 is arranged to cover the periphery of the oxide semiconductor layer 130, and the amount of hydrogen that diffuses inside the insulating layer 140 is minimized around the oxide semiconductor layer 130.

In the present embodiment, impurities that have passed through the insulating layer 140 are injected into the oxide semiconductor layer 130. On the other hand, impurities that have passed through the metal oxide layer 145 are injected into the insulating layer 140 (or the insulating layers 120 and 140) around the oxide semiconductor layer 130. Therefore, regardless of whether the insulating layer 140 overlaps the oxide semiconductor layer 130, hydrogen and oxygen are generated in the insulating layer 140 due to collision of impurity ions by the ion-implantation.

However, in the region around the oxide semiconductor layer 130 (i.e., the region where the metal oxide layer 145 is arranged), since the metal oxide layer 145 functions as a barrier layer that prevents oxygen from moving, it is possible to suppress the oxygen originally present inside the insulating layer 140 and the oxygen generated by the ion-implantation from diffusing upward (i.e., into the air). That is, in the region where the metal oxide layer 145 is arranged, the oxygen present inside the insulating layer 140 remains inside the insulating layer 140 without diffusing into the air.

As described above, hydrogen is also generated inside the insulating layer 140 by the ion-implantation, but the oxygen present inside the insulating layer 140 functions as a hydrogen trap that captures hydrogen. That is, the oxygen present inside the insulating layer 140 serves to suppress the diffusion of hydrogen that occurs during the subsequent heating process. Therefore, in the region around the oxide semiconductor layer 130 (the region where the metal oxide layer 145 is not arranged), the oxygen remaining inside the insulating layer 140 functions as a hydrogen trap, and diffusion of hydrogen is effectively suppressed. In this case, at the time of the ion-implantation, the region where the oxide semiconductor layer 130 is not formed occupies an overwhelmingly large area as compared with the region where the oxide semiconductor layer 130 is formed. That is, by arranging the metal oxide layer 145 around the oxide semiconductor layer 130, the amount of hydrogen generated in the vicinity of the oxide semiconductor layer 130 can be greatly reduced, and the decrease in channel resistance due to hydrogen-diffusion can be efficiently suppressed.

In addition, the opening 145-1 is provided on the region of the insulating layer 140 that overlaps the oxide semiconductor layer 130, and the metal oxide layer 145 is not arranged. Therefore, oxygen easily escapes into the atmosphere from the insulating layer 140 positioned above the source region SR and the drain region DR shown in FIG. 11. As a result, although hydrogen easily diffuses in the insulating layer 140 positioned above the source region SR and the drain region DR, the hydrogen diffusion in this case largely contributes to lowering the resistance of the source region SR and the drain region DR.

As described above, in the present embodiment, when impurities are added to the oxide semiconductor layer 130 to form the source region SR and the drain region DR, it is possible to retain a large amount of oxygen inside the insulating layer 140 positioned directly below the metal oxide layer 145 by arranging the metal oxide layer 145 around the oxide semiconductor layer 130. As a result, the diffusion of hydrogen within the insulating layer 140 positioned directly below the metal oxide layer 145 can be efficiently suppressed by oxygen. As a result, according to the present embodiment, the decrease in channel resistance due to hydrogen-diffusion can be suppressed, and a highly reliable semiconductor device can be manufactured.

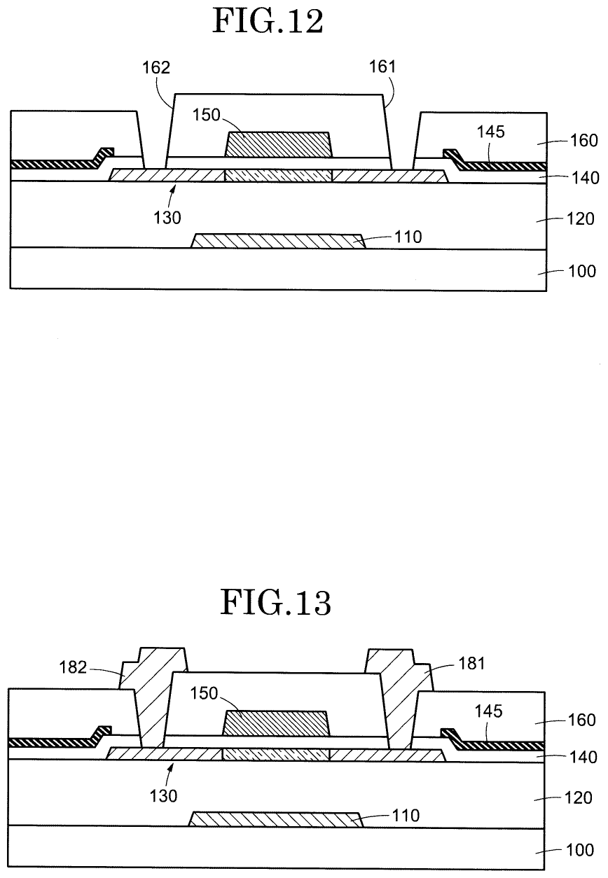

Next, as shown in FIG. 4 and FIG. 12, a third insulating layer (the insulating layer 160) is formed to cover the conductive layer 150 (step S1080). In the present embodiment, the insulating layer 160 having a stacked structure in which a silicon oxide layer and a silicon nitride layer are stacked in this order from the lower layer is formed by a plasma CVD method. Further, the contact holes 161 and 162 are formed in portions of the insulating layers 140 and 160 overlapping the source region SR and the drain region DR of the oxide semiconductor layer 130, respectively.

Next, as shown in FIG. 4 and FIG. 13, a third conductive layer (the conductive layers 181 and 182) is formed on the insulating layer 160 (step S1090). Specifically, the conductive layers 181 and 182 are formed by forming a three-layer metal layer formed of a titanium layer, an aluminum layer, and a titanium layer in this order by the sputtering method and patterning the metal layer into a predetermined shape. The conductive layers 181 and 182 are electrically connected to the oxide semiconductor layer 130 via the contact holes 161 and 162, respectively. That is, the conductive layer 181 is connected to the source region SR and functions as a source electrode, and the conductive layer 182 is connected to the drain region DR and functions as a drain electrode.

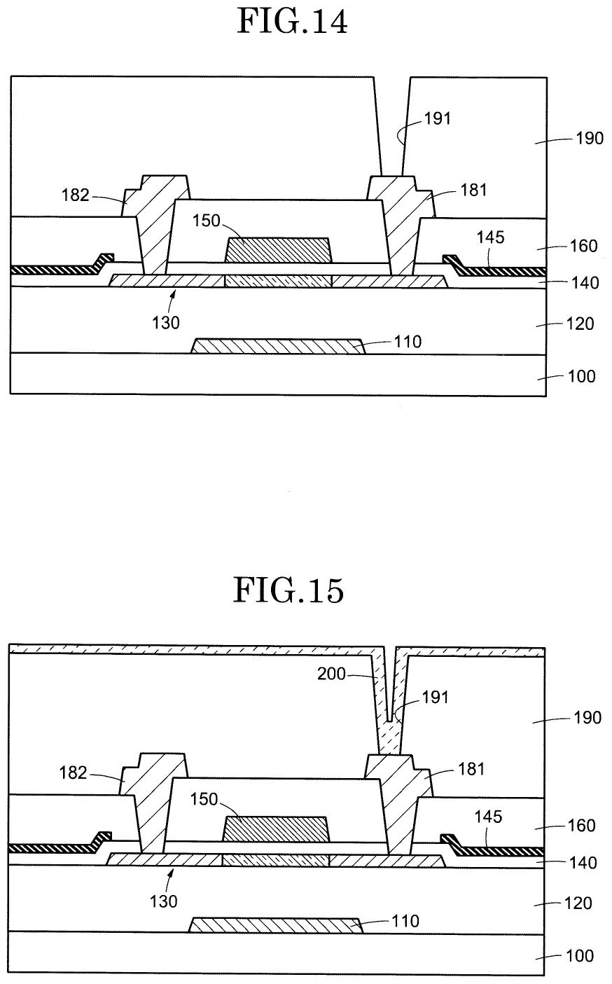

Next, as shown in FIG. 4 and FIG. 14, a fourth insulating layer (the insulating layer 190) is formed to cover the conductive layers 181 and 182 (step S1100). The insulating layer 190 of the present embodiment is formed by applying a resin material (for example, acryl or polyimide) by a solution-coating method. In the present embodiment, a photosensitive acryl material is used as the insulating layer 190. The insulating layer 190 having the contact hole 191 can be formed by performing exposure and photolithography using a photosensitive resin material. In the present embodiment, the contact hole 191 is formed in a part of the insulating layer 190 overlapping the conductive layer 181.

Although an example in which the insulating layer 190 is formed by the solution-coating method has been described in the present embodiment, the present invention is not limited to this example, and may be formed by other methods such as a printing method. The insulating layer 190 functions as a planarization layer. Therefore, a thickness of the insulating layer 190 is preferably 1 μm or more and 4 μm or less (preferably 2 μm or more and 3 μm or less).

Next, as shown in FIG. 4 and FIG. 15, the pixel electrode 200 is formed on the insulating layer 190 (step S1110). Specifically, a transparent conductive film (metal oxide film) is formed on the insulating layer 190 by the sputtering method, and is patterned into a predetermined pattern-shape to form the pixel electrode 200. In the present embodiment, ITO (Indium Tin Oxide), which is a metal oxide, is used as a material for forming the pixel electrode 200. The pixel electrode 200 is electrically connected to the conductive layer 181 functioning as a source electrode via the contact hole 191.

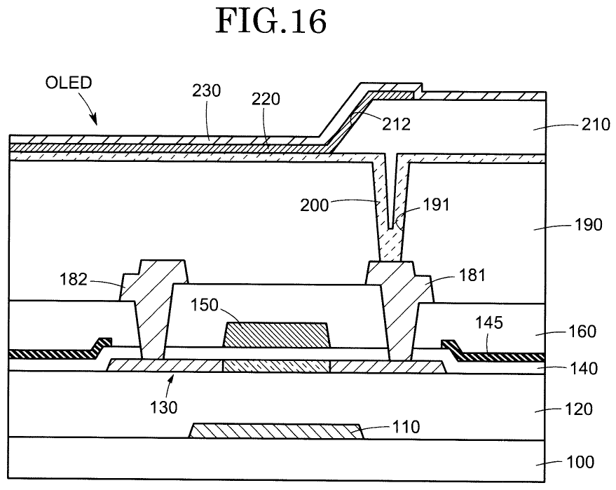

Next, as shown in FIG. 4 and FIG. 16, the bank 210 is formed on the pixel electrode 200 (step S1120). A resin material (for example, a photosensitive acrylic material) can be used as a material for forming the bank 210. Specifically, after the resin material is applied by the solution-coating method or the like, exposure and development are performed to form the bank 210 including the opening 212. As shown in FIG. 16, the opening 212 provided in the bank 210 exposes a majority of the upper surface of the pixel electrode 200.

After the bank 210 is formed, the light-emitting layer 220 composed of an organic EL material is formed to overlap the opening 212. In the present embodiment, the organic EL material that emits red, green, or blue light is formed as the light-emitting layer 220 by a vapor deposition method. The light-emitting layer 220 is formed to emit light of different colors for each pixel 13. That is, an organic EL material that emits red is used for the pixel 13 that emits red, an organic EL material that emits green is used for the pixel 13 that emits green, and an organic EL material that emits blue is used for the pixel 13 that emits blue. The light-emitting layer 220 may include an electron injection layer, an electron transport layer, an electron blocking layer, a hole injection layer, a hole transport layer, or a hole blocking layer as a functional layer composed of a functional material in addition to the light-emitting layer composed of a light-emitting material.

The common electrode 230 is formed on the light-emitting layer 220. In the present embodiment, a layer containing magnesium silver is formed as the common electrode 230 by the vapor deposition method. The common electrode 230 may be provided across a plurality of pixels. By forming the common electrode 230, the light-emitting element OLED formed of the pixel electrode 200, the light-emitting layer 220, and the common electrode 230 is formed.

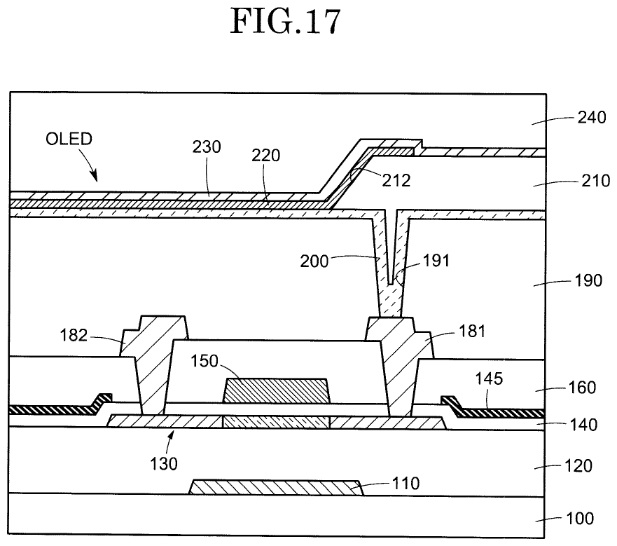

Finally, as shown in FIG. 4 and FIG. 17, the sealing layer 240 is formed to cover the light-emitting element OLED (step S1130). Although not shown in the diagram, the sealing layer 240 includes a stacked structure in which a silicon nitride layer, an organic resin layer (for example, an acryl layer), and a silicon nitride layer are stacked in this order from the lower layer. However, the present invention is not limited to this example, and a silicon oxide layer or an amorphous silicon layer may be provided between the silicon nitride layer and the organic resin layer. By providing these layers, adhesion between the silicon nitride layer and the organic resin layer can be improved. In addition, since the touch sensor 20 (see FIG. 1) is provided on the sealing layer 240 in the present embodiment, an overcoat layer may be provided on the sealing layer 240 for the purpose of planarization.

Through the above-described processes, the pixel 13 including the drive transistor DRT as the semiconductor device is completed. In the present embodiment, the hydrogen generated inside the insulating layer 140 during the ion-implantation can be retained around the oxide semiconductor layer 130. As a result, the hydrogen generated inside the insulating layer 140 during the ion-implantation can be effectively suppressed from diffusing during the subsequent heating process. Therefore, hydrogen-diffusion after ion-implantation can be effectively suppressed, and a highly reliable semiconductor device can be manufactured in which the decrease in channel resistance is suppressed.

First Modification of First Embodiment

As shown in FIG. 9A and FIG. 9B, the present embodiment exemplifies a configuration in which the position of the inner wall of the opening 145-1 of the metal oxide layer 145 and the position of the end portion of the oxide semiconductor layer 130 coincide with each other in the direction perpendicular to the substrate 100. However, the present invention is not limited to this example, the size of the opening RM1 may be larger or smaller than the size of the oxide semiconductor layer 130.

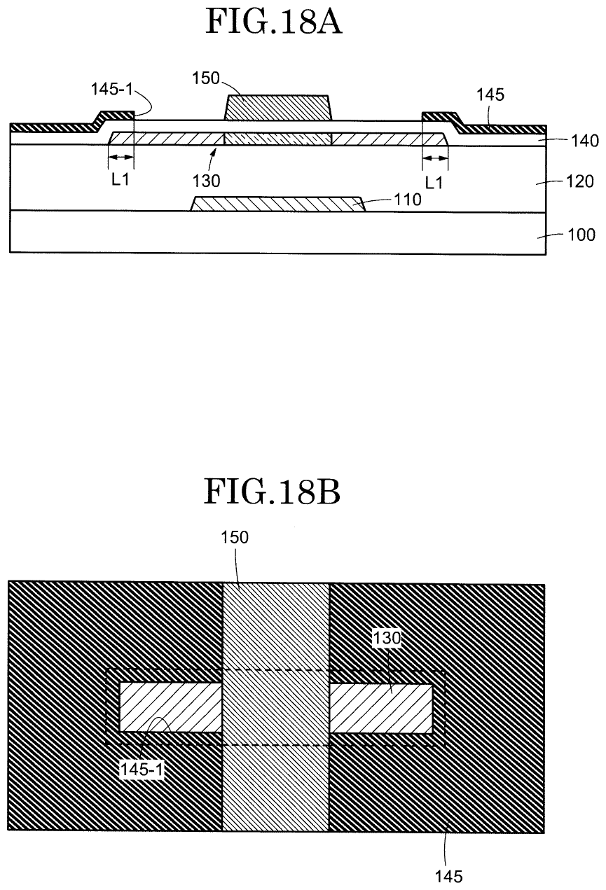

FIG. 18A is a schematic cross-sectional view showing a method for manufacturing the pixel 13 including the semiconductor device according to a modification of an embodiment of the present invention. FIG. 18B is a schematic plan view showing a method for manufacturing the pixel 13 including the semiconductor device according to a first modification of an embodiment of the present invention. In the present modification, the metal oxide layer 145 is arranged to overlap the end portion of the oxide semiconductor layer 130 by a predetermined distance (in this case, L1). Specifically, as shown in FIG. 18B, the metal oxide layer 145 is arranged along the outer periphery of the oxide semiconductor layer 130 to overlap the end portion of the oxide semiconductor layer 130 with the width of L1. Although there is no particular limitation on the possible range of the distance L1, it is desirable to set the distance L1 to 0.3 μm or more and 1.2 μm or less (preferably 0.5 μm or more and 1.0 μm or less).

If the distance L1 is too long, there is a risk that the resistance of the oxide semiconductor layer 130 will become high due to oxygen in the region where the metal oxide layer 145 and the oxide semiconductor layer 130 overlap. In other words, the effective area of the source region SR and the drain region DR may be reduced. In addition, if the metal oxide layer 145 exists in the region where the source region SR and the source electrode (conductive layer 181) are connected to each other and the drain region DR and the drain electrode (conductive layer 182) are connected to each other, etching defects may occur at the time of forming the contact hole. As described above, if the metal oxide layer 145 excessively overlaps the oxide semiconductor layer 130, this may cause a connection failure between the source electrode or the drain electrode and the oxide semiconductor layer 130.

In addition, if the distance L1 is too short, parts where the oxide semiconductor layer 130 and the metal oxide layer 145 overlap and do not overlap may be generated when the resist mask RM is misaligned, which may cause variation in the characteristics of the semiconductor device.

As described above, in the case of the first modification, the size of the opening 145-1 of the metal oxide layer 145 is smaller than the size of the oxide semiconductor layer 130. That is, in a plan view, the outer shape (outline) of the edge of the oxide semiconductor layer 130 includes the outer shape (outline) of the edge of the opening 145-1. With such a configuration, a region where the impurities remain in the insulating layer 140 can be made as large as possible. Therefore, the amount of hydrogen that diffuses from the periphery of the oxide semiconductor layer 130 toward the channel region CR can be greatly suppressed.

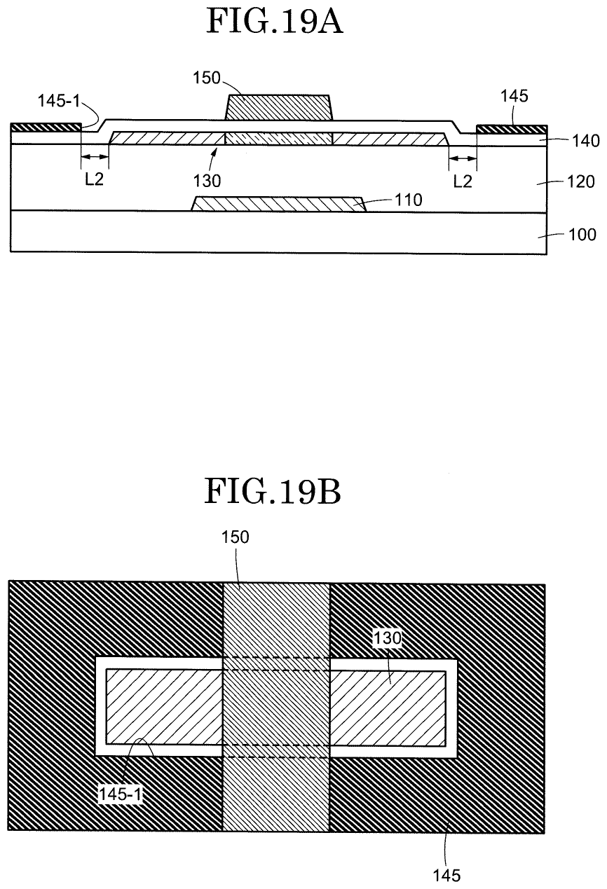

Next, FIG. 19A is a schematic cross-sectional view showing a method for manufacturing the pixel 13 including the semiconductor device according to the first modification of an embodiment of the present invention. FIG. 19B is a schematic plan view showing a method for manufacturing the pixel 13 including the semiconductor device according to the first modification of an embodiment of the present invention. In the present modification, the metal oxide layer 145 is arranged to be separated from the end portion of the oxide semiconductor layer 130 by a predetermined distance (in this case, L2). Specifically, as shown in FIG. 19B, the metal oxide layer 145 is arranged along the outer periphery of the oxide semiconductor layer 130 to be spaced apart from the oxide semiconductor layer 130 with the width of L2. Although there is no particular limitation on the possible range of the distance L2, it is desirable to set the distance L2 to 0.3 μm or more and 1.2 μm or less (preferably 0.5 μm or more and 1.0 μm or less).

If the distance L2 is too long, the exposed area of the insulating layer 140 is increased, which may lead to an increase in the amount of hydrogen generated inside the insulating layer 140. In addition, if the distance L2 is too short, when misalignment occurs at the time of forming the opening 145-1 of the metal oxide layer 145, the oxide semiconductor layer 130 and the metal oxide layer 145 overlap, which may reduce the effective area of the oxide semiconductor layer 130. If the oxide semiconductor layer 130 and the metal oxide layer 145 overlap in this manner, as described above, connection failure may occur between the source electrode or the drain electrode and the oxide semiconductor layer 130.

As described above, in the case of the first modification, the size of the opening 145-1 of the metal oxide layer 145 is larger than the size of the oxide semiconductor layer 130. That is, in a plan view, the outer shape (outline) of the edge of the opening 145-1 includes the outer shape (outline) of the edge of the oxide semiconductor layer 130. With such a configuration, the metal oxide layer 145 does not overlap the oxide semiconductor layer 130 (particularly the source region SR and the drain region DR), so that it is possible to prevent problems such as contact failure from occurring between the conductive layer 181 and the source region SR or between the conductive layer 182 and the drain region DR.

### Second Modification of First Embodiment

In the first embodiment, an example in which the metal oxide layer 145 formed in the step S1040 shown in FIG. 4 is subjected to a patterning process to remain around the oxide semiconductor layer 130 is shown, but the present invention is not limited to this example, and the metal oxide layer may be formed after the conductive layer 150 is formed.

For example, all of the metal oxide layer 145 formed in the above-described step S1040 is removed after the annealing for oxidation process. After that, the conductive layer 150 is formed on the insulating layer 140, and then a metal oxide layer having an opening overlapping the oxide semiconductor layer 130 may be formed. In this case, the metal oxide layer is arranged around the oxide semiconductor layer 130 and covers the upper surface and the side surface of the conductive layer 150 around the oxide semiconductor layer 130 (i.e., the region that does not overlap the oxide semiconductor layer 130).

### Second Embodiment

Although an example in which the channel region CR, the source region SR, and the drain region DR are provided in the oxide semiconductor layer 130 has been described in the first embodiment, an example in which a low resistance region HRR is provided in addition to these regions will be described in the present embodiment. In the description of the present embodiment, the same elements as those of the first embodiment are denoted by the same reference signs in the drawings, and the description thereof may be omitted.

### Pixel Structure

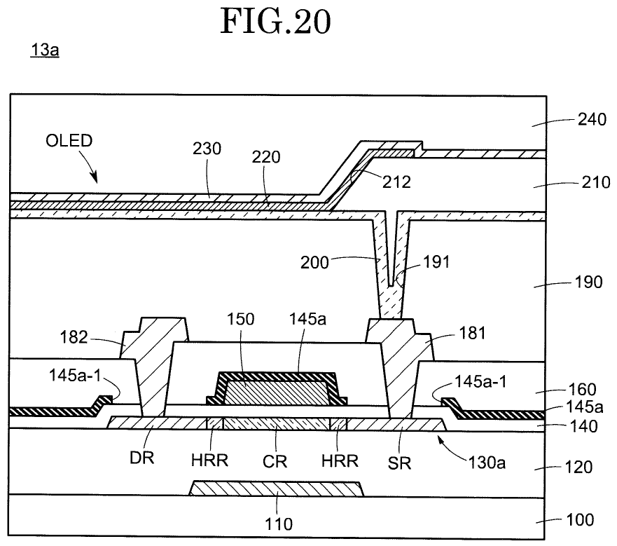

FIG. 20 is a schematic cross-sectional view showing a configuration of a pixel 13a including a semiconductor device according to an embodiment of the present invention. FIG. 20 shows the same basic structure as the pixel 13 shown in FIG. 3, but differs in the configuration of an oxide semiconductor layer 130a functioning as an active layer of the semiconductor device. Specifically, the oxide semiconductor layer 130a includes the low resistance region HRR between the channel region CR and the source region SR and between the channel region CR and the drain region DR, respectively.

The low resistance region HRR is a region that has relatively lower resistance than the channel region CR. However, the resistance in the low resistance region HRR is higher than the resistance in the source region SR and the drain region DR. The low resistance region HRR functions as a buffer region that suppresses the moving speed of carriers from the channel region CR toward the source region SR or the drain region DR. That is, the low resistance region HRR is functionally similar to a region commonly referred to as an LDD region.

In the present embodiment, a metal oxide layer 145a is provided to cover the conductive layer 150. Specifically, the metal oxide layer 145a covering an upper surface and a side surface of the conductive layer 150 and a part of the upper surface of the insulating layer 140 is provided. As a result, in the first embodiment, one opening 145-1 is arranged in the metal oxide layer 145 in one transistor, whereas in the present embodiment, two openings 145a-1 are provided in the metal oxide layer 145a in one transistor. As shown in FIG. 20, the two openings 145a-1 overlap the source region SR and the drains region DR provided in the oxide semiconductor layer 130a, respectively. In this case, a part of the metal oxide layer 145a covering the conductive layer 150 is in contact with the upper surface of the insulating layer 140 and overlaps the low resistance region HRR of the oxide semiconductor layer 130a.

### Method for Manufacturing Pixel

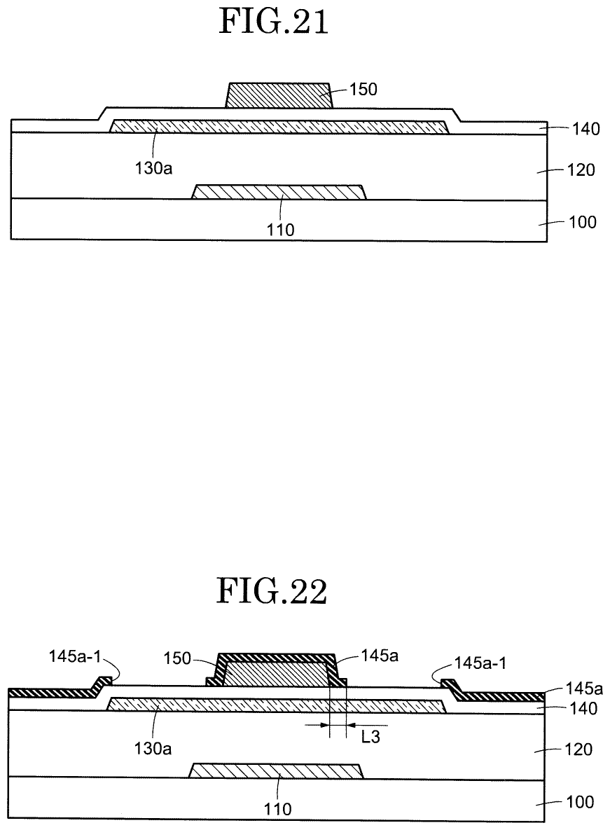

FIG. 21 to FIG. 24 are schematic cross-sectional views showing a method for manufacturing the pixel 13a including a semiconductor device according to an embodiment of the present invention.

First, the step S1010 to the step S1040 shown in FIG. 4 in the first embodiment are performed to complete the annealing for oxidation process of the oxide semiconductor layer 130a. After that, all of the metal oxide layer 145 provided on the insulating layer 140 is removed, and the conductive layer 150 (second conductive layer) is formed at a position overlapping the oxide semiconductor layer 130a. As a result, the state shown in FIG. 21 is obtained.

Next, as shown in FIG. 22, the metal oxide layer 145a is formed on the insulating layer 140 and the conductive layer 150. The metal oxide layer 145a may be formed using the same material and deposition conditions as those of the metal oxide layer 145 described in the first embodiment. In the present embodiment, an aluminum oxide (AlOₓ) layer having a thickness of 8 nm is formed as the metal oxide layer 145a by the sputtering method.

After the metal oxide layer 145a is formed, the metal oxide layer 145a is patterned to form the opening 145a-1. Specifically, a resist mask (not shown) is formed on the metal oxide layer 145a by photolithography, and the metal oxide layer 145a is etched by a wet etching process using hydrofluoric acid to form two openings 145a-1. In this case, the metal oxide layer 145a is left on the conductive layer 150 to cover the conductive layer 150.

As shown in FIG. 22, a part of the metal oxide layer 145a arranged to cover the conductive layer 150 is in contact with the upper surface of the insulating layer 140. Specifically, a part of the metal oxide layer 145a covering the conductive layer 150 is arranged to overlap the insulating layer 140 by a predetermined distance (in this case, L3). In other words, in FIG. 22, the opening 145a-1 is separated from the end portion of the conductive layer 150 by a predetermined distance L3. Although there is no particular limitation on the possible range of the distance L3, it is desirable to set the distance L3 to 0.5 μm or more and 3.0 μm or less (preferably 1.0 μm or more and 2.0 μm or less, more preferably 1.5 μm or more and 2.0 μm or less). The opening 145a-1 is formed to overlap the region of the oxide semiconductor layer 130a, which will later function as the source region SR and the drain region DR.

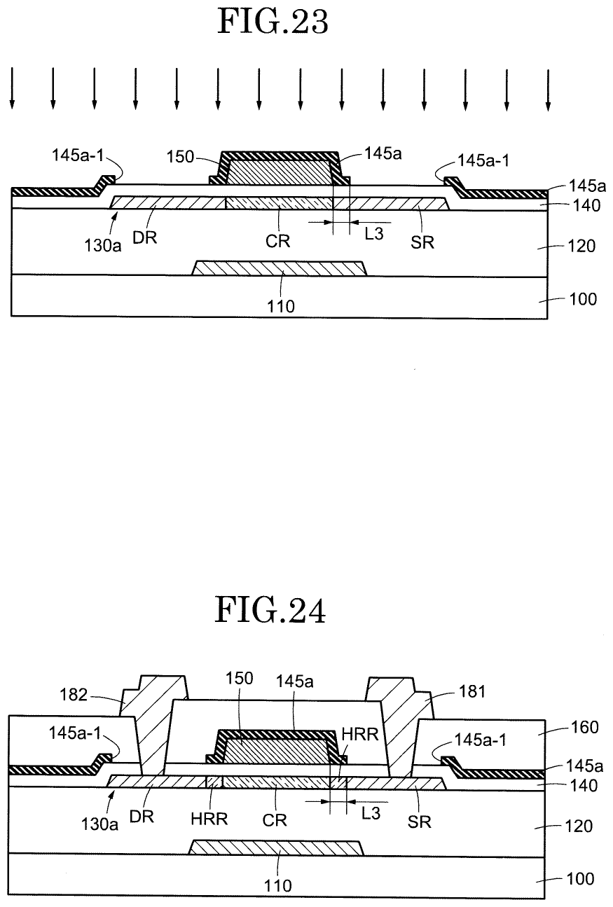

Next, as shown in FIG. 23, an impurity is injected into the oxide semiconductor layers 130a. The impurity injection process is similar to the process described in the step S1070 of FIG. 4. The channel region CR, the source region SR, and the drain region DR are formed in the oxide semiconductor layer 130a by performing the impurity injection process. In the present embodiment, the region directly below the conductive layer 150 becomes the channel region CR (region where no impurities are added). In addition, a part of the metal oxide layer 145a covering the conductive layer 150 that is in contact with the insulating layer 140 does not function as a mask in the impurity injection process. Therefore, an impurity is added to the oxide semiconductor layer 130a positioned directly below the part in contact with the insulating layer 140 in the metal oxide layer 145a covering the conductive layer 150.

After that, the state shown in FIG. 24 is obtained by forming the insulating layer 160, the conductive layer 181, and the conductive layer 182 according to the step S1080 and the step S1090 shown in FIG. 4 of the first embodiment.

During the process of forming the insulating layer 160, the conductive layer 181, and the conductive layer 182 as shown in FIG. 24, the oxide semiconductor layer 130 and the insulating layer 140 are heated. In the case of the present embodiment, a large amount of oxygen, which is suppressed from diffusing due to the metal oxide layer 145a, remains directly below a part in contact with the insulating layer 140 in the metal oxide layer 145a covering the conductive layer 150. Therefore, due to heating in the process of forming the insulating layer 160, the conductive layer 181, and the conductive layer 182, the oxygen remaining inside the insulating layer 140 diffuses into the oxide semiconductor layer 130. As a result, oxygen defects formed in the oxide semiconductor layer 130 by the impurity injection process are repaired by oxygen again, and the resistance of the oxide semiconductor layer 130 increases. That is, the resistance of the oxide semiconductor layer 130 positioned directly below the part in contact with the insulating layer 140 in the metal oxide layer 145a covering the conductive layer 150 increases.

As described above, in the present embodiment, a region with a lower resistance than the channel region CR and a higher resistance than the source region SR and the drain region DR, i.e., the low resistance region HRR, is formed between the channel region CR and the source region SR and between the channel region CR and the drain region DR. As described above, in the present embodiment, the channel region CR and the low resistance region HRR are formed in a self-aligned manner. In the present embodiment, the width of the low resistance region HRR in the channel direction is L3.

Also in the present embodiment, similar to the first embodiment, when the impurity is injected into the oxide semiconductor layer 130, the metal oxide layer 145a is arranged around the oxide semiconductor layer 130, so that the hydrogen diffusion due to the subsequent heating process can be suppressed. Therefore, according to the present embodiment, the decrease in channel resistance due to hydrogen-diffusion can be efficiently suppressed.

### Third Embodiment

In the present embodiment, an example is shown in which a semiconductor device is manufactured in a method different from that of the first embodiment. Specifically, in the present embodiment, a metal oxide layer 145b is left between the insulating layer 140 and the conductive layer 150. In the description of the present embodiment, the same elements as those of the first embodiment are denoted by the same reference signs in the drawings, and the description thereof may be omitted.

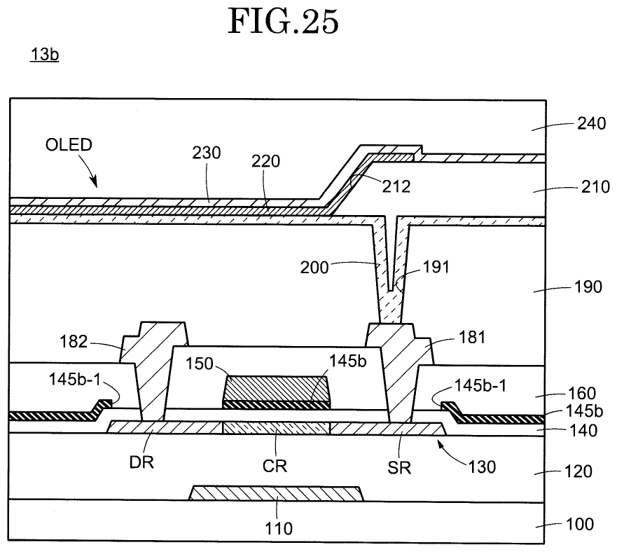

FIG. 25 is a schematic cross-sectional view showing a configuration of a pixel 13b including a semiconductor device according to an embodiment of the present invention. FIG. 25 is similar to the pixel 13 shown in FIG. 3, except that the metal oxide layer 145b is interposed between the insulating layer 140 and the conductive layer 150.

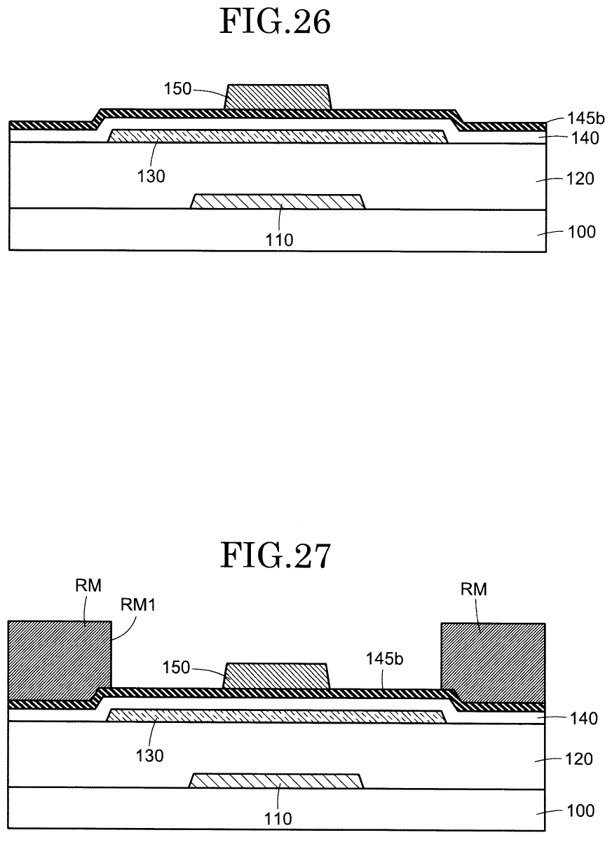

FIG. 26 to FIG. 29 are schematic cross-sectional views showing a method for manufacturing the pixel 13b including a semiconductor device according to an embodiment of the present invention.

First, the step S1010 to the step S1040 shown in FIG. 4 in the first embodiment are performed to complete the annealing for oxidation process of the oxide semiconductor layer 130. After that, the conductive layer 150 (second conductive layer) is formed at a position overlapping the oxide semiconductor layer 130 on the metal oxide layer 145b. As a result, the state shown in FIG. 26 is obtained.

In the present embodiment, a molybdenum-tungsten alloy is used as a constituent material of conductive layer 150, and aluminum oxide is used as a constituent material of the metal oxide layer 145b. In this case, by using a dry etching process using a fluorine-based gas in the patterning process for forming the conductive layer 150, the selectivity between the conductive layer 150 and the metal oxide layer 145b can be ensured.

Next, as shown in FIG. 27, a resist mask RM is formed on the metal oxide layer 145b. The resist mask RM has an opening RM1 at a position overlapping the oxide semiconductor layer 130. In other words, the resist mask RM is formed in a region that does not overlap the oxide semiconductor layer 130. Specifically, the position of the inner wall of the opening RM1 and the position of the end portion of the oxide semiconductor layer 130 coincide with each other in the direction perpendicular to the substrate 100. That is, in a plan view, the outer shape of the edge of the opening RM1 coincides with the outer shape of the edge of the oxide semiconductor layer 130.

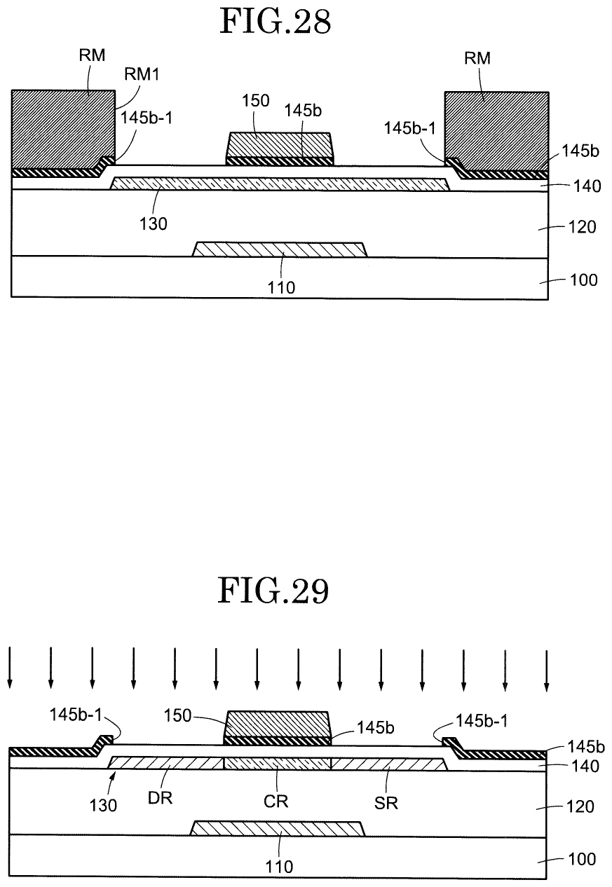

Next, as shown in FIG. 28, an etching process is performed on the metal oxide layer 145b using the resist mask RM and the conductive layer 150 as a mask to form two openings 145b-1. In this case, the etching process is performed by a wet etching process using hydrofluoric acid. By using hydrofluoric acid as an etchant, not only the resist mask RM but also the conductive layer 150 can be used as a mask. Further, in the present embodiment, since the thickness of the metal oxide layer 145b is 10 nm or less, the etching process is completed in a very short time. Therefore, by controlling the etching time, it is possible to minimize overetching of the insulating layer 140 that is exposed after etching of the metal oxide layer 145b.

Next, as shown in FIG. 29, after the resist mask RM is removed, an impurity is added to the oxide semiconductor layer 130 using the ion-implantation method. As a result, the channel region CR, the source region SR, and the drain region DR are formed in the oxide semiconductor layer 130.

Since the processes after the impurity injection process shown in FIG. 29 are similar to those in the first embodiment, redundant description will be omitted. Further, in the present embodiment, since the function of the metal oxide layer 145b arranged around the oxide semiconductor layer 130 is also similar to that of the first embodiment, description will be omitted. According to the present embodiment, the amount of hydrogen generated in the vicinity of the oxide semiconductor layer 130 can be greatly reduced, and the decrease in channel resistance due to hydrogen-diffusion can be efficiently suppressed. As a result, the decrease in channel resistance due to hydrogen-diffusion can be suppressed, and a highly reliable semiconductor device can be manufactured.

### Modification of Third Embodiment

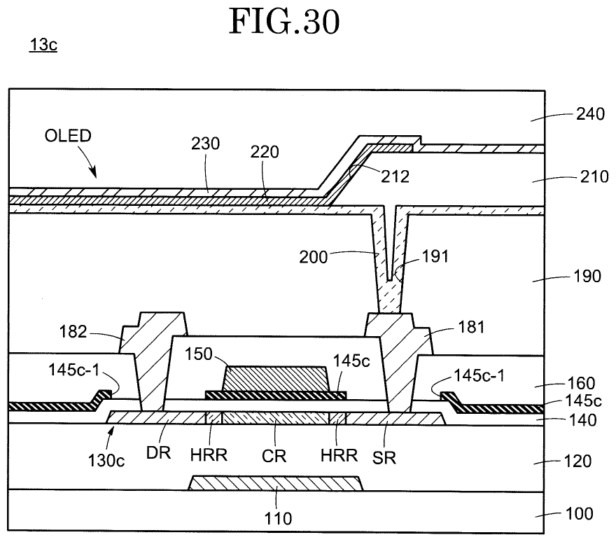

FIG. 30 is a schematic cross-sectional view showing a configuration of a pixel 13c including a semiconductor device according to a modification of an embodiment of the present invention. FIG. 30 shows the same basic structure as the pixel 13 shown in FIG. 25, but differs in the configuration of an oxide semiconductor layer 130c functioning as an active layer of the semiconductor device. Specifically, the oxide semiconductor layer 130c includes the low resistance region HRR between the channel region CR and the source region SR and between the channel region CR and the drain region DR, respectively.

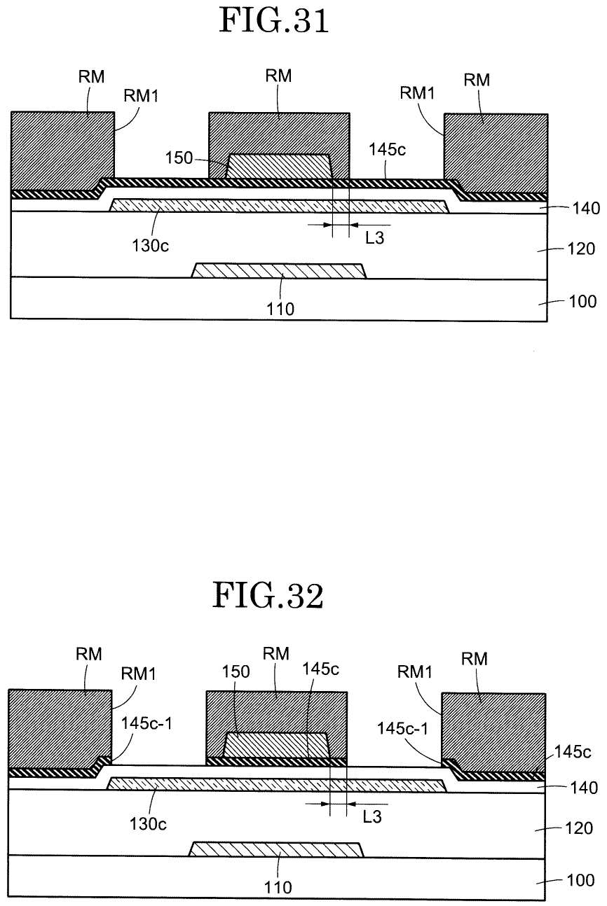

FIG. 31 to FIG. 34 are schematic cross-sectional views showing a method for manufacturing the pixel 13c including a semiconductor device according to a modification of an embodiment of the present invention.

First, after passing through the process shown in FIG. 26 described above, as shown in FIG. 31, the resist mask RM is formed on a metal oxide layer 145c. The resist mask RM is formed on the conductive layer 150 in addition to the region that does not overlap the oxide semiconductor layers 130. Specifically, in FIG. 31, the resist mask RM that covers the upper surface and the side surface of the conductive layer 150 and a part of the upper surface of the insulating layer 140 is provided in addition to the resist mask RM provided at the position shown in FIG. 27. As a result, in FIG. 31, two openings RM1 are provided in the resist mask RM in one transistor.

In this case, a part of the resist mask RM that covers the conductive layer 150 is arranged to overlap the insulating layer 140 by a predetermined distance (in this case, L3). In other words, in FIG. 31, the opening RM1 is separated from the end portion of the conductive layer 150 by a predetermined distance L3. Although there is no particular limitation on the possible range of the distance L3, it is desirable to set the distance L3 to 0.5 μm or more and 3.0 μm or less (preferably 1.0 μm or more and 2.0 μm or less, more preferably 1.5 μm or more and 2.0 μm or less). The opening RM1 is formed to overlap the region of the oxide semiconductor layers 130a, which will later function as the source region SR and the drain region DR.

Next, as shown in FIG. 32, an etching process is performed on the metal oxide layer 145c using the resist mask RM as a mask to form two openings 145c-1. The etching process is performed by a wet etching process using hydrofluoric acid. However, the present invention is not limited to this example, and either a wet etching process or dry etching process may be used as long as the metal oxide layer 145c can be etched. However, it is desirable to minimize the over-etching of the insulating layer 140 exposed after the etching of the metal oxide layer 145c.

The metal oxide layer 145c remains between the insulating layer 140 and the conductive layer 150 due to the process shown in FIG. 32. As shown in FIG. 32, the width in the channel direction of the metal oxide layer 145c arranged between the insulating layer 140 and the conductive layer 150 is wider than the width in the channel direction of the conductive layer 150 by a predetermined distance (twice L3). That is, a part of the metal oxide layer 145c positioned between the insulating layer 140 and the conductive layer 150 that does not overlap the conductive layer 150 (hereinafter, referred to as a “non-overlapping part of the metal oxide layer 145c”) protrudes from the conductive layer 150 toward the channel direction, and covers the insulating layer 140.

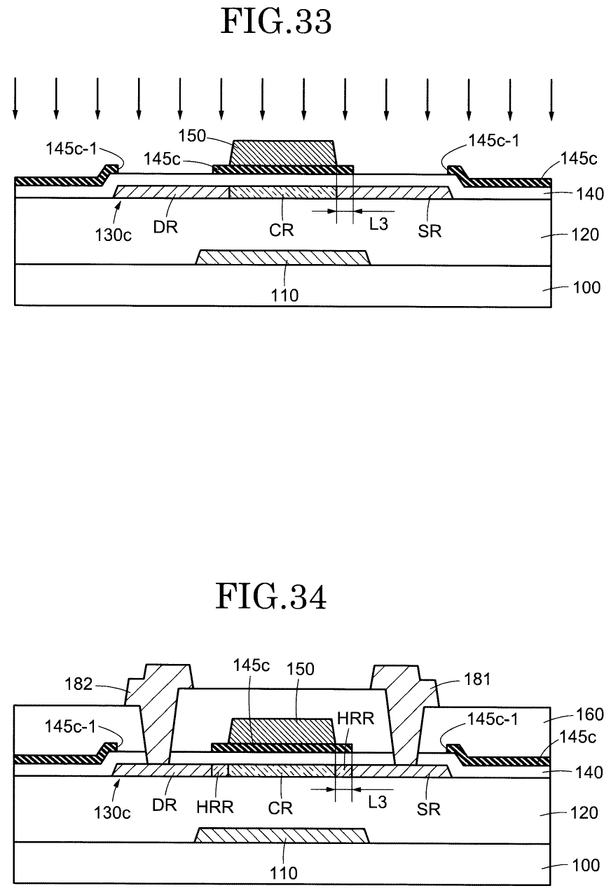

Next, after the resist mask RM is removed, as shown in FIG. 33, an impurity is injected into the oxide semiconductor layer 130c. The impurity injection process is similar to the process described in the step S1070 of FIG. 4. The channel region CR, the source region SR, and the drain region DR are formed in the oxide semiconductor layers 130c by performing the impurity injection process. In the present modification, the region directly below the conductive layer 150 becomes the channel region CR (region where no impurities are added). In addition, the non-overlapping part of the metal oxide layer 145c does not function as a mask in the impurity injection process. Therefore, an impurity is added to the oxide semiconductor layer 130c positioned directly below the non-overlapping part of the metal oxide layer 145c.

After that, by forming the third insulating layer 160, the conductive layer 181, and the conductive layer 182 according to the step S1080 and the step S1090 shown in FIG. 4 of the first embodiment, the state shown in FIG. 34 is obtained.

During the process of forming the third insulating layer 160, the conductive layer 181, and the conductive layer 182 as shown in FIG. 34, the oxide semiconductor layer 130 and the insulating layer 140 are heated. In the case of the present embodiment, a large amount of oxygen that is suppressed from diffusing due to the metal oxide layer 145c remains directly below the non-overlapping part of the metal oxide layer 145c. Therefore, due to the heating in the process of forming the third insulating layer 160, the conductive layer 181, and the conductive layer 182, the oxygen remaining in the insulating layer 140 diffuses into the oxide semiconductor layer 130. As a result, the oxygen defects formed in the oxide semiconductor layer 130 by the impurity injection process are repaired by oxygen again, and the resistance of the oxide semiconductor layer 130 increases. That is, the resistance of the oxide semiconductor layer 130 positioned directly below the non-overlapping part of the metal oxide layer 145c increases.

As described above, in the present embodiment, a region with a lower resistance than the channel region CR and a higher resistance than the source region SR and the drain region DR, i.e., the low resistance region HRR, is formed between the channel region CR and the source region SR and between the channel region CR and the drain region DR. As described above, in the present embodiment, the channel region CR and the low resistance region HRR are formed in a self-aligned manner. In the present embodiment, the width of the low resistance region HRR in the channel direction is L3.

Also in the present embodiment, similar to the first embodiment, when the impurity is injected into the oxide semiconductor layer 130c, the metal oxide layer 145c is arranged around the oxide semiconductor layer 130c, so that the hydrogen diffusion due to the subsequent heating process can be suppressed. Therefore, according to the present embodiment, the decrease in channel resistance due to hydrogen-diffusion can be efficiently suppressed.

Each of the above-described embodiments (including the modifications) as the embodiment of the present invention can be appropriately combined and implemented as long as there is no contradiction. Furthermore, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device comprising:
an oxide semiconductor layer;
a gate insulating layer on the oxide semiconductor layer;
a metal oxide layer having an opening overlapping at least a portion of the oxide semiconductor layer and contacting an upper surface of the gate insulating layer in a region not overlapping the oxide semiconductor layer, and
a gate electrode on the gate insulating layer in a region overlapping the oxide semiconductor layer.

2. The semiconductor device according to claim 1, wherein
an outline of an edge of the opening matches an outline of an edge of the oxide semiconductor layer in a plan view.

3. The semiconductor device according to claim 1, wherein
the outline of the edge of the oxide semiconductor layer includes the outline of the edge of the opening in a plan view.

4. The semiconductor device according to claim 3, wherein
the metal oxide layer overlaps a portion of the oxide semiconductor layer along the edge of the oxide semiconductor layer.

5. The semiconductor device according to claim 1, wherein
the outline of the edge of the opening includes the outline of the edge of the oxide semiconductor layer in a plan view.

6. The semiconductor device according to claim 5, wherein
a distance from the edge of the opening to the edge of the oxide semiconductor layer is 0.3 μm or more and 1.2 μm or less.

7. The semiconductor device according to claim 1, wherein
the gate electrode is in contact with the metal oxide layer in the region not overlapping the oxide semiconductor layer.

8. The semiconductor device according to claim 1, wherein
the opening has a first opening overlapping a source region of the oxide semiconductor layer and a second opening overlapping a drain region of the oxide semiconductor layer.

9. The semiconductor device according to claim 8, wherein
a portion of the metal oxide layer covers an upper surface and a side surface of the gate electrode and is in contact with the gate insulating layer in the region overlapping the oxide semiconductor layer.

10. The semiconductor device according to claim 8, wherein
a portion of the metal oxide layer is disposed between the gate insulating layer and the gate electrode in the region overlapping the oxide semiconductor layer.

11. The semiconductor device according to claim 1, wherein
the metal oxide layer includes aluminum oxide (AlOx), aluminum oxynitride (AlOxNy), aluminum nitride oxide (AlNxOy), or aluminum nitride (AlNx).

12. The semiconductor device according to claim 1, wherein the thickness of the metal oxide layer is 20 nm or less.

13. A display device including the semiconductor device according to claim 1.

14. A method for manufacturing a semiconductor device, the method comprising:
forming an oxide semiconductor layer on an insulating surface;
forming a gate insulating layer on the oxide semiconductor layer;
forming a metal oxide layer having an opening overlapping at least a portion of the oxide semiconductor layer and in contact with an upper surface of the gate insulating layer;
forming a gate electrode on the gate insulating layer, and
injecting an impurity to the oxide semiconductor layer via the gate insulating layer.

15. The method according to claim 14, wherein
the metal oxide layer is formed by a sputtering method.

16. The method according to claim 14, wherein
the metal oxide layer includes aluminum oxide (AlOx), aluminum oxynitride (AlOxNy), aluminum nitride oxide (AlNxOy), or aluminum nitride (AlNx).

17. The method according to claim 14, wherein
the thickness of the metal oxide layer is 20 nm or less.

18. The method according to claim 14, wherein
an outline of an edge of the opening matches an outline of an edge of the oxide semiconductor layer in a plan view.

19. The method according to claim 14, wherein
the outline of the edge of the oxide semiconductor layer includes the outline of the edge of the opening in a plan view.

20. The method according to claim 14, wherein
the outline of the edge of the opening includes the outline of the edge of the oxide semiconductor layer in a plan view.
